(19) United States
(12) Patent Application Publication
(10) Pub. No.: US 2018/0025905 A1
(43) Pub. Date: Jan. 25, 2018

(54) SEMICONDUCTOR DEVICE AND METHOD FOR MANUFACTURING THE SAME

(71) Applicant: Semiconductor Energy Laboratory Co., Ltd., Atsugi-shi (JP)

(72) Inventors: Shunpei YAMAZAKI, Setagaya (JP); Yasutaka NAKAZAWA, Tochigi (JP); Takuya HANDA, Moka (JP); Masahiro WATANABE, Tochigi (JP)

(73) Assignee: Semiconductor Energy Laboratory Co., Ltd.

(21) Appl. No.: 15/654,105

(22) Filed: Jul. 19, 2017

(30) Foreign Application Priority Data
Jul. 25, 2016 (JP) 2016-145096

(51) Int. Cl. H01L 21/02; H01L 27/04; H01L 51/52; H01L 29/49; H01L 29/786

(52) U.S. Cl. CPC H01L 21/02104; H01L 29/4908; H01L 29/7869; H01L 51/5203; H01L 27/04

(57) ABSTRACT

A semiconductor device having favorable electrical characteristics is provided. A highly reliable semiconductor device is provided. The semiconductor device includes a metal oxide. The semiconductor device includes a gate electrode, a first insulating film over the gate electrode, the metal oxide over the first insulating film, a pair of electrodes over the metal oxide, and a second insulating film in contact with the metal oxide. The metal oxide includes a first metal oxide and a second metal oxide in contact with a top surface of the first metal oxide. The first metal oxide and the second metal oxide each contain In, an element M (M is gallium, aluminum, silicon, or the like), and Zn. The first metal oxide includes a region having lower crystallinity than the second metal oxide. The second insulating film includes a region whose thickness is smaller than that of the second metal oxide.

### BACKGROUND OF THE INVENTION

### 1. Field of the Invention

One embodiment of the present invention relates to a semiconductor device including a metal oxide. Another embodiment of the present invention relates to a method for manufacturing the semiconductor device.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter. In particular, one embodiment of the present invention relates to a semiconductor device, a display device, a light-emitting device, a power storage device, a memory device, a driving method thereof, and a manufacturing method thereof.

In this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. An imaging device, a display device, a liquid crystal display device, a light-emitting device, an electro-optical device, a power generation device (including a thin film solar cell, an organic thin film solar cell, and the like), and an electronic device may each include a semiconductor device.

### 2. Description of the Related Art

As a semiconductor material that can be used in a transistor, an oxide has been attracting attention. For example, Patent Document 1 discloses a field-effect transistor including an amorphous oxide of any of an In—Zn—Ga—O-based oxide, an In—Zn—Ga—Mg—O-based oxide, an In—Zn—O-based oxide, an In—Sn—O-based oxide, an In—O-based oxide, an In—Ga—O-based oxide, and a Sn—In—Zn—O-based oxide.

Non-Patent Document 1 discusses a structure including a metal oxide with two stacked layers of an In—Zn—O-based oxide and an In—Ga—Zn—O-based oxide as an active layer of a transistor.

### REFERENCES

### Patent Document

[Patent Document 1] Japanese Patent No. 5118810

### Non-Patent Document

[Non-Patent Document 1] John F. Wager, “Oxide TFTs: A Progress Report”, Information Display 1/16, SID 2016, January/February 2016, Vol. 32, No. 1, pp. 16-21

### SUMMARY OF THE INVENTION

In Patent Document 1, an active layer of a transistor is formed using an amorphous oxide of any of an In—Zn—Ga—O-based oxide, an In—Zn—Ga—Mg—O-based oxide, an In—Zn—O-based oxide, an In—Sn—O-based oxide, an In—O-based oxide, an In—Ga—O-based oxide, and a Sn—In—Zn—O-based oxide. In other words, the active layer of the transistor includes one of the amorphous oxides. The transistor whose active layer includes one of the amorphous oxides has a problem in that on-state current, which is one of electrical characteristics of the transistor, is small. Alternatively, the transistor whose active layer includes one of the amorphous oxides has a problem of decreased reliability.

In Non-Patent Document 1, a channel-protective bottom-gate transistor achieves high field-effect mobility (μ=62 cm²V⁻¹s⁻¹). An active layer of the transistor is a two-layer stack of an In—Zn oxide and an In—Ga—Zn oxide, and the thickness of the In—Zn oxide where a channel is formed is 10 nm. However, the S value (the subthreshold swing (SS)), which is one of transistor characteristics, is as large as 0.41 V/decade. Moreover, the threshold voltage (Vₜₕ), which is also one of transistor characteristics, is −2.9 V, which means that the transistor has a normally-on characteristic.

In view of the above problems, an object of one embodiment of the present invention is to provide a semiconductor device with favorable electrical characteristics. Another object of one embodiment of the present invention is to provide a highly reliable semiconductor device. Another object of one embodiment of the present invention is to provide a semiconductor device having a novel structure. Another object of one embodiment of the present invention is to provide a method for manufacturing a semiconductor device having a novel structure.

Note that the descriptions of these objects do not disturb the existence of other objects. In one embodiment of the present invention, there is no need to achieve all the objects. Other objects will be apparent from and can be derived from the description of the specification, the drawings, the claims, and the like.

One embodiment of the present invention is a semiconductor device including a metal oxide. The semiconductor device includes a gate electrode, a first insulating film over the gate electrode, the metal oxide over the first insulating film, a pair of electrodes over the metal oxide, and a second insulating film in contact with the metal oxide. The metal oxide includes a first metal oxide and a second metal oxide in contact with a top surface of the first metal oxide. The first metal oxide and the second metal oxide each contain In, an element M (M is gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, or magnesium), and Zn. The first metal oxide includes a region having lower crystallinity than the second metal oxide. The second insulating film includes a region whose thickness is smaller than that of the second metal oxide.

Another embodiment of the present invention is a semiconductor device including a metal oxide. The semiconductor device includes a gate electrode, a first insulating film over the gate electrode, the metal oxide over the first insulating film, a pair of electrodes over the metal oxide, and a second insulating film in contact with the metal oxide. The metal oxide includes a first metal oxide, a second metal oxide in contact with a top surface of the first metal oxide, and a third metal oxide in contact with a bottom surface of the first metal oxide. The first metal oxide, the second metal oxide, and the third metal oxide each contain In, an element M (M is gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, or magnesium), and Zn. The first metal oxide includes a region having lower crystallinity than the second metal oxide. The second insulating film includes a region whose thickness is smaller than that of the second metal oxide.

In the above embodiment, the second insulating film preferably contains silicon and one or both of nitrogen and oxygen. In the above embodiment, the second insulating film preferably includes a first layer containing silicon and oxygen and a second layer containing silicon and nitrogen. In the above embodiment, the second insulating film preferably includes a region with a thickness of greater than or equal to 0.3 nm and less than or equal to 10 nm.

In the above embodiment, the semiconductor device preferably includes a third insulating film over the second insulating film. The third insulating film preferably contains a resin material.

In the above embodiment, the first metal oxide and the second metal oxide each preferably include a region where the number of In atoms is greater than or equal to 40% and less than or equal to 50% of the total number of In, M, and Zn atoms, and a region where the number of M atoms is greater than or equal to 5% and less than or equal to 30% of the total number of In, M, and Zn atoms.

In the above embodiment, the first metal oxide and the second metal oxide each preferably have an atomic ratio where, when In is 4 with respect to the total number of In, M, and Zn atoms, M is greater than or equal to 1.5 and less than or equal to 2.5 and Zn is greater than or equal to 2 and less than or equal to 4.

In the above embodiment, the first metal oxide and the second metal oxide each preferably have an atomic ratio where, when In is 5 with respect to the total number of In, M, and Zn atoms, M is greater than or equal to 0.5 and less than or equal to 1.5 and Zn is greater than or equal to 5 and less than or equal to 7.

In the above embodiment, it is preferable that a peak not be observed at 28 of around 31° in the first metal oxide and that a peak be observed at 28 of around 31° in the second metal oxide by XRD analysis.

In the above embodiment, the first metal oxide, the second metal oxide, and the third metal oxide each preferably have an atomic ratio where, when In is 4 with respect to the total number of In, M, and Zn atoms, M is greater than or equal to 1.5 and less than or equal to 2.5 and Zn is greater than or equal to 2 and less than or equal to 4.

In the above embodiment, the first metal oxide, the second metal oxide, and the third metal oxide each preferably have an atomic ratio where, when In is 5 with respect to the total number of In, M, and Zn atoms, M is greater than or equal to 0.5 and less than or equal to 1.5 and Zn is greater than or equal to 5 and less than or equal to 7.

In the above embodiment, it is preferable that a peak not be observed at 28 of around 31° in the first metal oxide and that a peak be observed at 28 of around 31° in the second metal oxide and the third metal oxide by XRD analysis.

Another embodiment of the present invention is a method for manufacturing a semiconductor device including a metal oxide. The method includes the steps of forming a gate electrode over a substrate, forming a first insulating film over the substrate and the gate electrode, forming the metal oxide over the first insulating film, forming a pair of electrodes over the metal oxide, and forming a second insulating film over the metal oxide. The step of forming the second insulating film is performed in a vacuum chamber of a CVD apparatus and includes the following three steps. In a first step, a source gas is supplied to the vacuum chamber to attach the source gas to the metal oxide. In a second step, the source gas is evacuated. In a third step, one or both of a nitrogen gas and an oxygen gas are supplied to the vacuum chamber to generate plasma on the metal oxide.

Another embodiment of the present invention is a method for manufacturing a semiconductor device including a metal oxide. The method includes the steps of forming a gate electrode over a substrate, forming a first insulating film over the substrate and the gate electrode, forming the metal oxide over the first insulating film, forming a pair of electrodes over the metal oxide, and forming a second insulating film over the metal oxide. The step of forming the second insulating film is performed in a vacuum chamber of a CVD apparatus and includes the following seven steps. In a first step, a source gas is supplied to the vacuum chamber to attach the source gas to the metal oxide. In a second step, the source gas is evacuated. In a third step, an oxygen gas is supplied to the vacuum chamber to generate plasma on the metal oxide, so that a first layer containing silicon and oxygen is formed on the metal oxide. In a fourth step, an oxygen gas is supplied to the vacuum chamber to add oxygen to the first layer. In a fifth step, the source gas is supplied to the vacuum chamber to attach the source gas to the first layer. In a sixth step, the source gas is evacuated. In a seventh step, a nitrogen gas is supplied to the vacuum chamber to generate plasma on the first layer, so that a second layer containing silicon and nitrogen is formed on the first layer.

In the above embodiment, the source gas preferably contains silane.

According to one embodiment of the present invention, a semiconductor device can be provided with favorable electrical characteristics. According to one embodiment of the present invention, a highly reliable semiconductor device can be provided. According to one embodiment of the present invention, a semiconductor device having a novel structure can be provided. According to one embodiment of the present invention, a method for manufacturing a semiconductor device having a novel structure can be provided.

Note that the descriptions of these effects do not disturb the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

In the accompanying drawings:

FIGS. 1A to 1C are a top view and cross-sectional views of a semiconductor device;

FIGS. 2A to 2C are a top view and cross-sectional views of a semiconductor device;

FIGS. 3A to 3C are a top view and cross-sectional views of a semiconductor device;

FIGS. 4A to 4C are a top view and cross-sectional views of a semiconductor device;

FIGS. 5A to 5C are a top view and cross-sectional views of a semiconductor device;

FIGS. 6A to 6C are a top view and cross-sectional views of a semiconductor device;

FIGS. 7A to 7C are cross-sectional views illustrating a method for manufacturing a semiconductor device;

FIGS. 8A to 8C are cross-sectional views illustrating a method for manufacturing a semiconductor device;

FIGS. 9A to 9C are cross-sectional views illustrating a method for manufacturing a semiconductor device;

FIGS. 10A to 10C are cross-sectional views illustrating a method for manufacturing a semiconductor device;

FIGS. 11A and 11B are cross-sectional views illustrating a method for manufacturing a semiconductor device;

FIG. 12 is a flow chart showing a method for forming an insulating film;

FIG. 13 is a flow chart showing a method for forming an insulating film;

FIGS. 14A and 14B each show an energy band;

FIG. 15 is a cross-sectional view illustrating a concept of a composition of a metal oxide;

FIG. 16 is a cross-sectional view illustrating a concept of a composition of a metal oxide;

FIG. 17 is a top view illustrating one embodiment of a display device;

FIG. 18 is a cross-sectional view illustrating one embodiment of a display device;

FIG. 19 is a cross-sectional view illustrating one embodiment of a display device;

FIG. 20 illustrates a structure example of a display panel;

FIG. 21 illustrates a structure example of a display panel;

FIG. 22 illustrates a display module;

FIGS. 23A to 23E illustrate electronic devices; and

FIGS. 24A to 24G illustrate electronic devices.

### DETAILED DESCRIPTION OF THE INVENTION

Hereinafter, embodiments will be described with reference to drawings. However, the embodiments can be implemented in many different modes, and it will be readily appreciated by those skilled in the art that modes and details thereof can be changed in various ways without departing from the spirit and scope of the present invention. Thus, the present invention should not be interpreted as being limited to the following description of the embodiments.

In the drawings, the size, the layer thickness, or the region is exaggerated for clarity in some cases. Therefore, the size, the layer thickness, or the region is not limited to the illustrated scale. Note that the drawings are schematic views showing ideal examples, and embodiments of the present invention are not limited to shapes or values shown in the drawings.

Note that in this specification, ordinal numbers such as “first”, “second”, and “third” are used in order to avoid confusion among components, and the terms do not limit the components numerically.

In this specification, terms for describing arrangement, such as “over”, “above”, “under”, and “below”, are used for convenience in describing a positional relation between components with reference to drawings. Furthermore, the positional relationship between components is changed as appropriate in accordance with a direction in which each component is described. Thus, there is no limitation on terms used in this specification, and description can be made appropriately depending on the situation.

In this specification and the like, a transistor is an element having at least three terminals of a gate, a drain, and a source. The transistor includes a channel region between the drain (a drain terminal, a drain region, or a drain electrode) and the source (a source terminal, a source region, or a source electrode), and current can flow between the source and the drain through the channel region. Note that in this specification and the like, a channel region refers to a region through which current mainly flows.

Furthermore, functions of a source and a drain might be switched when transistors having different polarities are employed or a direction of current flow is changed in circuit operation, for example. Therefore, the terms “source” and “drain” can be switched in this specification and the like.

Note that in this specification and the like, the term “electrically connected” includes the case where components are connected through an “object having any electric function”. There is no particular limitation on an “object having any electric function” as long as electric signals can be transmitted and received between components that are connected through the object. Examples of an “object having any electric function” are a switching element such as a transistor, a resistor, an inductor, a capacitor, and an element with a variety of functions as well as an electrode and a wiring.

In this specification and the like, the term “parallel” indicates that the angle formed between two straight lines is greater than or equal to −10° and less than or equal to 10°, and accordingly also includes the case where the angle is greater than or equal to −5° and less than or equal to 5°. The term “perpendicular” indicates that the angle formed between two straight lines is greater than or equal to 80° and less than or equal to 100°. Thus, the case where the angle is greater than or equal to 85° and less than or equal to 95° is also included.

In this specification and the like, the terms “film” and “layer” can be interchanged with each other. For example, in some cases, the term “conductive layer” can be changed into the term “conductive film”, and the term “insulating film” can be changed into the term “insulating layer”.

Unless otherwise specified, off-state current in this specification and the like refers to drain current of a transistor in an off state (also referred to as a non-conducting state and a cutoff state). Unless otherwise specified, the off state of an n-channel transistor means that the voltage between its gate and source (V_{gs}: gate-source voltage) is lower than the threshold voltage Vₜₕ, and the off state of a p-channel transistor means that the gate-source voltage V_{gs} is higher than the threshold voltage Vₜₕ. For example, the off-state current of an n-channel transistor sometimes refers to drain current that flows when the gate-source voltage V_{gs} is lower than the threshold voltage Vₜₕ.

The off-state current of a transistor depends on V_{gs} in some cases. Thus, “the off-state current of a transistor is lower than or equal to I” may mean “there is V_{gs} with which the off-state current of the transistor becomes lower than or equal to I”. Furthermore, “the off-state current of a transistor” means “the off-state current in an off state at predetermined V_{gs}”, “the off-state current in an off state at V_{gs} in a predetermined range”, “the off-state current in an off state at V_{gs} with which sufficiently reduced off-state current is obtained”, for example.

As an example, the assumption is made of an n-channel transistor where the threshold voltage Vₜₕ is 0.5 V and the drain current is 1×10⁻⁹ A at V_{gs} of 0.5 V, 1×10⁻¹³ A at V_{gs} of 0.1 V, 1×10⁻¹⁹ A at V_{gs} of −0.5 V, and 1×10⁻²² A at V_{gs} of −0.8 V. The drain current of the transistor is 1×10⁻¹⁹ A or lower at V_{gs} of −0.5 V or at V_{gs} in the range of −0.8 V to −0.5 V; therefore, it can be said that the off-state current of the transistor is 1×10⁻¹⁹ A or lower. Since there is V_{gs} at which the drain current of the transistor is 1×10⁻²² A or lower, it may be said that the off-state current of the transistor is 1×10⁻²² A or lower.

In this specification and the like, the off-state current of a transistor with a channel width W is sometimes represented by a current value per channel width W or by a current value per given channel width (e.g., 1 μm). In the latter case, the off-state current may be expressed in the unit with the dimension of current per length (e.g., A/μm).

The off-state current of a transistor depends on temperature in some cases. Unless otherwise specified, the off-state current in this specification may be off-state current at room temperature, 60° C., 85° C., 95° C., or 125° C. Alternatively, the off-state current may be off-state current at a temperature at which the reliability of a semiconductor device or the like including the transistor is ensured or a temperature at which the semiconductor device or the like including the transistor is used (e.g., temperature in the range of 5° C. to 35° C.). The description “the off-state current of a transistor is lower than or equal to I” may refer to a situation where there is V_{gs} at which the off-state current of a transistor is lower than or equal to I at room temperature, 60° C., 85° C., 95° C., 125° C., a temperature at which the reliability of a semiconductor device or the like including the transistor is ensured, or a temperature at which the semiconductor device or the like including the transistor is used (e.g., temperature in the range of 5° C. to 35° C.).

The off-state current of a transistor depends on voltage V_{ds} between its drain and source in some cases. Unless otherwise specified, the off-state current in this specification may be off-state current at V_{ds} of 0.1 V, 0.8 V, 1 V, 1.2 V, 1.8 V, 2.5 V, 3 V, 3.3 V, 10 V, 12 V, 16 V, or 20 V. Alternatively, the off-state current may be off-state current at V_{ds} at which the reliability of a semiconductor device or the like including the transistor is ensured or V_{ds} at which the semiconductor device or the like including the transistor is used. The description “the off-state current of a transistor is lower than or equal to I” may refer to a situation where there is V_{gs} at which the off-state current of the transistor is lower than or equal to I at V_{ds} of 0.1 V, 0.8 V, 1 V, 1.2 V, 1.8 V, 2.5 V, 3 V, 3.3 V, 10 V, 12 V, 16 V, or 20 V, at V_{ds} at which the reliability of a semiconductor device or the like including the transistor is ensured, or at V_{ds} at which the semiconductor device or the like including the transistor is used.

In the above description of off-state current, a drain may be replaced with a source. That is, the off-state current sometimes refers to current that flows through a source of a transistor in an off state.

In this specification and the like, the term “leakage current” sometimes expresses the same meaning as “off-state current”. In this specification and the like, the off-state current sometimes refers to current that flows between a source and a drain of a transistor in the off state, for example.

In this specification and the like, the threshold voltage of a transistor refers to a gate voltage (V_{g}) at which a channel is formed in the transistor. Specifically, in a graph where the horizontal axis represents the gate voltage (V_{g}) and the vertical axis represents the square root of drain current (I_{d}), the threshold voltage of a transistor may refer to a gate voltage (V_{g}) at the intersection of the square root of drain current (I_{d}) of 0 (I_{d}=0 A) and an extrapolated straight line that is tangent with the highest inclination to a plotted curve (V_{g}−√I_{d} characteristics). Alternatively, the threshold voltage of a transistor may refer to a gate voltage (V_{g}) at which the value of I_{d} [A]×L [μm]/W [μm] is 1×10⁻⁹ [A] where L is channel length and W is channel width.

In this specification and the like, a “semiconductor” includes characteristics of an “insulator” in some cases when the conductivity is sufficiently low, for example. Furthermore, a “semiconductor” and an “insulator” cannot be strictly distinguished from each other in some cases because a border between the “semiconductor” and the “insulator” is not clear. Accordingly, a “semiconductor” in this specification and the like can be called an “insulator” in some cases. Similarly, an “insulator” in this specification and the like can be called a “semiconductor” in some cases. An “insulator” in this specification and the like can be called a “semi-insulator” in some cases.

In this specification and the like, a “semiconductor” includes characteristics of a “conductor” in some cases when the conductivity is sufficiently high, for example. Furthermore, a “semiconductor” and a “conductor” cannot be strictly distinguished from each other in some cases because a border between the “semiconductor” and the “conductor” is not clear. Accordingly, a “semiconductor” in this specification can be called a “conductor” in some cases. Similarly, a “conductor” in this specification and the like can be called a “semiconductor” in some cases.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. For example, a metal oxide used in an active layer of a transistor is called an oxide semiconductor in some cases. That is, a metal oxide that has at least one of an amplifying function, a rectifying function, and a switching function can be called a metal oxide semiconductor, or OS for short. In other words, an OS FET is a transistor including a metal oxide or an oxide semiconductor.

In this specification and the like, a metal oxide including nitrogen is also called a metal oxide in some cases. Moreover, a metal oxide including nitrogen may be called a metal oxynitride.

### Embodiment 1

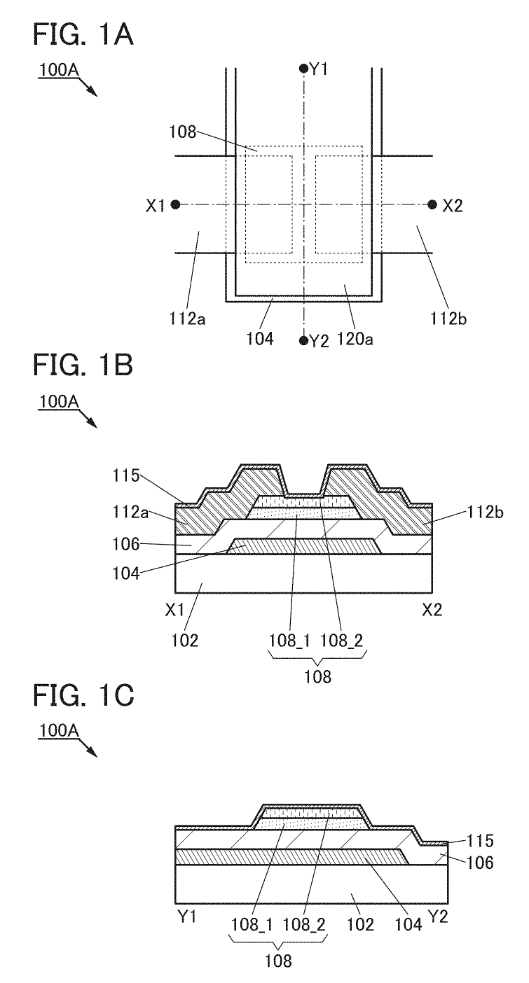

In this embodiment, a semiconductor device of one embodiment of the present invention and a method for manufacturing the semiconductor device are described with reference to FIGS. 1A to 1C, FIGS. 2A to 2C, FIGS. 3A to 3C, FIGS. 4A to 4C, FIGS. 5A to 5C, FIGS. 6A to 6C, FIGS. 7A to 7C, FIGS. 8A to 8C, FIGS. 9A to 9C, FIGS. 10A to 10C, FIGS. 11A and 11B, FIG. 12, FIG. 13, and FIGS. 14A and 14B.

### <1-1. Structure Example 1 of Semiconductor Device>

FIG. 1A is a top view of a transistor 100A that is a semiconductor device of one embodiment of the present invention. FIG. 1B is a cross-sectional view taken along the dashed-dotted line X1-X2 in FIG. 1A, and FIG. 1C is a cross-sectional view taken along the dashed-dotted line Y1-Y2 in FIG. 1A. Note that in FIG. 1A, some components of the transistor 100A (e.g., an insulating film functioning as a gate insulating film) are not illustrated to avoid complexity. The direction of the dashed-dotted line X1-X2 may be called a channel length direction, and the direction of the dashed-dotted line Y1-Y2 may be called a channel width direction. As in FIG. 1A, some components are not illustrated in some cases in top views of transistors described below.

The transistor 100A includes a conductive film 104 over a substrate 102, an insulating film 106 over the substrate 102 and the conductive film 104, a metal oxide 108 over the insulating film 106, a conductive film 112a over the metal oxide 108, and a conductive film 112b over the metal oxide 108. Furthermore, an insulating film 115 is formed over the transistor 100A, specifically, over the metal oxide 108, the conductive film 112a, and the conductive film 112b.

Note that the transistor 100A is what is called a channel-etched transistor.

The insulating film 115 preferably contains silicon and one or both of nitrogen and oxygen. Furthermore, the insulating film 115 preferably includes a region with a thickness of greater than or equal to 0.3 nm and less than or equal to 10 nm. As the insulating film 115, for example, a layered film of a first layer containing silicon and oxygen and a second layer containing silicon and nitrogen is preferably used. Note that the insulating film 115 is preferably formed by a plasma assisted atomic layer deposition (PAALD) method. By a PAALD method, the insulating film 115 having high coverage can be formed.

When the insulating film 115 is formed by a PAALD method, the insulating film 115 can be formed using a manufacturing line of amorphous silicon (a-Si). For example, when a semiconductor layer of a transistor is formed using a metal oxide instead of a-Si, apparatus in the existing manufacturing line can be used with a small additional capital investment and the like.

The insulating film 115 can be formed by a PAALD method in the following manner, for example: an SiH₄ gas is introduced as a source gas into a vacuum chamber of a PECVD apparatus, the SiH₄ gas is attached to surfaces of the metal oxide 108 and the conductive films 112a and 112b at the atomic level, the source gas is evacuated, and plasma treatment is performed using a nitrogen gas or an oxygen gas.

Note that a PAALD method is suitable as a method for forming an insulating film over the metal oxide 108, i.e., an insulating film on the back channel side of the metal oxide 108, because a PAALD method causes less damage during film formation.

The metal oxide 108 includes a metal oxide 108_1 over the insulating film 106 and a metal oxide 108_2 in contact with a top surface of the metal oxide 108_1.

Note that the metal oxide 108_1 and the metal oxide 1082 each contain In, an element M (M is gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, or magnesium), and Zn. In particular, the element M is preferably gallium.

The metal oxide 108_1 and the metal oxide 108_2 each include a region where the number of In atoms is greater than or equal to 40% and less than or equal to 50% of the total number of In, M, and Zn atoms, and a region where the number of M atoms is greater than or equal to 5% and less than or equal to 30% of the total number of In, M, and Zn atoms. When the metal oxide 108_1 and the metal oxide 1082 each include the above regions, the carrier density can be increased.

Specifically, the atomic ratio of In to M and Zn in each of the metal oxide 108_1 and the metal oxide 108_2 is preferably In:M:Zn=4:2:3 or a neighborhood of In:M:Zn=4:2:3, or In:M:Zn=5:1:6 or a neighborhood of In:M:Zn=5:1:6. Note that In:M:Zn=4:2:3 or a neighborhood of In:M:Zn=4:2:3 refers to an atomic ratio where, when In is 4 with respect to the total number of In, M, and Zn atoms, M is greater than or equal to 1.5 and less than or equal to 2.5 and Zn is greater than or equal to 2 and less than or equal to 4. Furthermore, In:M:Zn=5:1:6 or a neighborhood of In:M:Zn=5:1:6 refers to an atomic ratio where, when In is 5 with respect to the total number of In, M, and Zn atoms, M is greater than or equal to 0.5 and less than or equal to 1.5 and Zn is greater than or equal to 5 and less than or equal to 7.

The metal oxide 108_1 preferably includes a region having lower crystallinity than the metal oxide 108_2. When the metal oxide 108_1 includes the region having lower crystallinity than the metal oxide 108_2, the metal oxide 108_1 can have a higher carrier density; accordingly, a semiconductor device with high reliability can be provided. For example, the metal oxide 108_2 having higher crystallinity than the metal oxide 108_1 serves as an etching stopper for the metal oxide 108_1 because the transistor 100A is the channel-etched transistor.

When the atomic ratio of In to M and Zn in the metal oxide 1082 is in the above range, the contact resistance between the metal oxide 108_2 and the conductive films 112a and 112b can be reduced.

When the thicknesses of the metal oxide 108_2 and the insulating film 115 are compared with each other, the insulating film 115 is preferably thinner than the metal oxide 108_2. By making the insulating film 115 thinner than the metal oxide 108_2, an influence of the stress of the insulating film 115 on the metal oxide 108_2 can be reduced. Thus, a transistor in which a change in electrical characteristics is small can be provided.

When the metal oxide 108 has the above structure, the transistor 100A can have high field-effect mobility. Specifically, the field-effect mobility of the transistor 100A can be higher than 50 cm²/Vs, preferably higher than 100 cm²/Vs.

For example, the use of the transistor with high field-effect mobility in a gate driver that generates a gate signal allows a display device to have a narrow frame. The use of the transistor with high field-effect mobility in a source driver (particularly in a demultiplexer connected to an output terminal of a shift register included in the source driver) that is included in a display device and supplies a signal from a signal line can reduce the number of wirings connected to the display device.

Note that crystal structures of the metal oxide 108_1 and the metal oxide 108_2 are not particularly limited. The metal oxide 108_1 and the metal oxide 108_2 may each have one or both of a single crystal structure and a non-single crystal structure.

The non-single crystal structure includes, for example, a c-axis aligned crystalline oxide semiconductor (CAAC-OS) described later, a polycrystalline structure, a microcrystalline structure, and an amorphous structure. Examples of the crystal structure also include a bixbyite crystal structure and a layered crystal structure. A mixed crystal structure including a bixbyite crystal structure and a layered crystal structure may be used.

The metal oxide 108_2 preferably has a layered crystal structure, in particular, a crystal structure having c-axis alignment. In other words, the metal oxide 108_2 is preferably a CAAC-OS.

It is preferable that the metal oxide 108_1 have a microcrystalline structure and the metal oxide 108_2 have a crystal structure having c-axis alignment, for example. That is, the metal oxide 108_1 includes a region having lower crystallinity than the metal oxide 108_2. Note that the crystallinity of the metal oxide 108 can be determined by analysis by X-ray diffraction (XRD) or with a transmission electron microscope (TEM), for example.

For example, when the metal oxide 108 is measured by XRD analysis, a peak at 2θ of around 31° is hardly observed in the metal oxide 108_1 but is observed in the metal oxide 1082.

In the case where the metal oxide 108_1 includes a region having low crystallinity, the following advantageous effects can be achieved.

First, oxygen vacancies that might be formed in the metal oxide 108_1 are described.

Oxygen vacancies formed in the metal oxide 108_1 adversely affect the transistor characteristics and therefore cause a problem. For example, oxygen vacancies formed in the metal oxide 108_1 are bonded to hydrogen to serve as a carrier supply source. The carrier supply source generated in the metal oxide 108_1 causes a change in the electrical characteristics, typically, a shift in the threshold voltage, of the transistor 100A including the metal oxide 108_1. Therefore, it is preferable that the amount of oxygen vacancies in the metal oxide 108_1 be as small as possible.

In view of the above, in one embodiment of the present invention, the metal oxide 1082 is formed over the metal oxide 108_1. The metal oxide 1082 contains a larger amount of oxygen than the metal oxide 108_1. Oxygen or excess oxygen is transferred from the metal oxide 1082 to the metal oxide 108_1 at the time of or after the formation of the metal oxide 108_2, whereby oxygen vacancies in the metal oxide 108_1 can be reduced.

By being formed in an atmosphere containing a large amount of oxygen, the metal oxide 108_2 can have high crystallinity.

Increasing the crystallinity of the metal oxide 108_2 can inhibit impurities that may enter the metal oxide 108_1. In particular, the higher crystallinity of the metal oxide 108_2 can inhibit damage to the metal oxide 108_1 at the time of processing the conductive films 112a and 112b. The surface of the metal oxide 108, i.e., the surface of the metal oxide 108_2 is exposed to an etchant or an etching gas at the time of processing the conductive films 112a and 112b. The metal oxide 108_2 has etching resistance superior to the metal oxide 108_1 owing to its region having higher crystallinity than the metal oxide 108_1. Thus, the metal oxide 108_2 serves as an etching stopper.

Note that it is preferable to use, as the metal oxide 108, a metal oxide in which the impurity concentration is low and the density of defect states is low, in which case the transistor can have more excellent electrical characteristics. Here, the state in which the impurity concentration is low and the density of defect states is low (the amount of oxygen vacancies is small) is referred to as “highly purified intrinsic” or “substantially highly purified intrinsic”. Note that impurities in a metal oxide are typically water, hydrogen, and the like. In this specification and the like, reducing or removing water and hydrogen from the metal oxide is referred to as dehydration or dehydrogenation in some cases. Moreover, adding oxygen to the metal oxide is referred to as oxygen addition in some cases, and a state in which oxygen in excess of the stoichiometric composition is contained due to the oxygen addition is referred to as an oxygen-excess state in some cases.

A highly purified intrinsic or substantially highly purified intrinsic metal oxide has few carrier generation sources and thus can have a low carrier density. Thus, a transistor in which a channel region is formed in the metal oxide rarely has a negative threshold voltage (is rarely normally on). The highly purified intrinsic or substantially highly purified intrinsic metal oxide has a low density of defect states and accordingly has a low density of trap states in some cases. Furthermore, the highly purified intrinsic or substantially highly purified intrinsic metal oxide has an extremely low off-state current; even when an element has a channel width W of 1×10⁶ μm and a channel length L of 10 μm, the off-state current can be less than or equal to the measurement limit of a semiconductor parameter analyzer, i.e., less than or equal to 1×10⁻¹³ A, at a voltage (drain voltage) between a source electrode and a drain electrode of from 1 V to 10 V.

By including a region having lower crystallinity than the metal oxide 108_2, the metal oxide 108_1 sometimes has a high carrier density. When the metal oxide 108_1 has a high carrier density, the Fermi level is sometimes high relative to the conduction band of the metal oxide 108_1. This lowers the conduction band minimum of the metal oxide 108_1, so that the energy difference between the conduction band minimum of the metal oxide 108_1 and the trap level, which might be formed in a gate insulating film (here, the insulating film 106), is increased in some cases. The increase of the energy difference can reduce trap of charges in the gate insulating film and reduce a change in the threshold voltage of the transistor, in some cases. In addition, when the metal oxide 108_1 has a high carrier density, the metal oxide 108 can have high field-effect mobility.

In the transistor 100A illustrated in FIGS. 1A to 1C, the insulating film 106 functions as a gate insulating film of the transistor 100A, and the insulating film 115 functions as a protective insulating film of the transistor 100A. Furthermore, in the transistor 100A, the conductive film 104 functions as a gate electrode, the conductive film 112a functions as a source electrode, and the conductive film 112b functions as a drain electrode. Note that in this specification and the like, the insulating film 106 may be referred to as a first insulating film, and the insulating film 115 may be referred to as a second insulating film.

### <1-2. Components of Semiconductor Device>

Next, components of the semiconductor device of this embodiment are described in detail.

### [Substrate]

There is no particular limitation on a material and the like of the substrate 102 as long as the material has heat resistance high enough to withstand at least heat treatment to be performed later. For example, a glass substrate, a ceramic substrate, a quartz substrate, or a sapphire substrate may be used as the substrate 102. Alternatively, a single crystal semiconductor substrate or a polycrystalline semiconductor substrate made of silicon, silicon carbide, or the like, a compound semiconductor substrate made of silicon germanium or the like, an SOI substrate, or the like can be used, or any of these substrates provided with a semiconductor element may be used as the substrate 102. In the case where a glass substrate is used as the substrate 102, a glass substrate having any of the following sizes can be used: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be fabricated.

Alternatively, a flexible substrate may be used as the substrate 102, and the transistor 100A may be provided directly on the flexible substrate. Alternatively, a separation layer may be provided between the substrate 102 and the transistor 100A. The separation layer can be used when part or the whole of a semiconductor device formed over the separation layer is separated from the substrate 102 and transferred onto another substrate. In such a case, the transistor 100A can be transferred to a substrate having low heat resistance or a flexible substrate.

### [Conductive Film]

The conductive film 104 functioning as a gate electrode, the conductive film 112a functioning as a source electrode, and the conductive film 112b functioning as a drain electrode can each be formed using a metal element selected from chromium (Cr), copper (Cu), aluminum (Al), gold (Au), silver (Ag), zinc (Zn), molybdenum (Mo), tantalum (Ta), titanium (Ti), tungsten (W), manganese (Mn), nickel (Ni), iron (Fe), and cobalt (Co); an alloy including any of these metal elements as its component; an alloy including a combination of any of these metal elements; or the like.

Furthermore, the conductive films 104, 112a, and 112b can be formed using an oxide conductor or an oxide semiconductor, such as an oxide including indium and tin (In—Sn oxide), an oxide including indium and tungsten (In—W oxide), an oxide including indium, tungsten, and zinc (In—W—Zn oxide), an oxide including indium and titanium (In—Ti oxide), an oxide including indium, titanium, and tin (In—Ti—Sn oxide), an oxide including indium and zinc (In—Zn oxide), an oxide including indium, tin, and silicon (In—Sn—Si oxide), or an oxide including indium, gallium, and zinc (In—Ga—Zn oxide).

Here, an oxide conductor is described. In this specification and the like, an oxide conductor may be referred to as OC. For example, oxygen vacancies are formed in an oxide semiconductor, and then hydrogen is added to the oxygen vacancies, so that a donor level is formed in the vicinity of the conduction band. This increases the conductivity of the oxide semiconductor; accordingly, the oxide semiconductor becomes a conductor. The oxide semiconductor having become a conductor can be referred to as an oxide conductor. Oxide semiconductors generally transmit visible light because of their large energy gaps. An oxide conductor is an oxide semiconductor having a donor level in the vicinity of the conduction band. Therefore, the influence of absorption due to the donor level is small in an oxide conductor, and an oxide conductor has a visible light transmitting property comparable to that of an oxide semiconductor.

A Cu—X alloy film (X is Mn, Ni, Cr, Fe, Co, Mo, Ta, or Ti) may be used for the conductive films 104, 112a, and 112b. The use of a Cu—X alloy film results in lower fabrication costs because the film can be processed by wet etching.

Among the above-mentioned metal elements, any one or more elements selected from copper, titanium, tungsten, tantalum, and molybdenum are preferably included in the conductive films 112a and 112b. In particular, a tantalum nitride film is preferably used as the conductive films 112a and 112b. A tantalum nitride film has conductivity and a high barrier property against copper or hydrogen. Because a tantalum nitride film releases little hydrogen from itself, it can be favorably used as the conductive film in contact with the metal oxide 108 or the conductive film in the vicinity of the metal oxide 108. It is favorable to use a copper film for the conductive films 112a and 112b because the resistance of the conductive films 112a and 112b can be reduced.

The conductive films 112a and 112b can be formed by electroless plating. As a material that can be deposited by electroless plating, for example, one or more elements selected from Cu, Ni, Al, Au, Sn, Co, Ag, and Pd can be used. It is further favorable to use Cu or Ag because the resistance of the conductive film can be reduced.

### [Insulating Film Functioning as Gate Insulating Film]

As the insulating film 106 functioning as a gate insulating film of the transistor 100A, an insulating layer including at least one of the following films formed by a plasma enhanced chemical vapor deposition (PECVD) method, a sputtering method, or the like can be used: a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film. Note that the insulating film 106 may have a stacked-layer structure or a stacked layer structure of three or more layers.

The insulating film 106 that is in contact with the metal oxide 108 functioning as a channel region of the transistor 100A is preferably an oxide insulating film and preferably includes a region including oxygen in excess of the stoichiometric composition (oxygen-excess region).

Note that one embodiment of the present invention is not limited to the above structure, and a nitride insulating film may be used as the insulating film that is in contact with the metal oxide 108. In one example, a silicon nitride film is formed and a surface of the silicon nitride film is oxidized by performing oxygen plasma treatment or the like on the surface of the silicon nitride film. In the case where oxygen plasma treatment or the like is performed on the surface of the silicon nitride film, the surface of the silicon nitride film may be oxidized at the atomic level. For this reason, oxygen might be undetectable by cross-sectional observation or the like of the transistor. That is, in the case of performing cross-sectional observation of the transistor, the silicon nitride film and the metal oxide may be observed to be in contact with each other in some cases.

Note that the silicon nitride film has a higher dielectric constant than a silicon oxide film and needs a larger thickness for capacitance equivalent to that of the silicon oxide film. Thus, when the silicon nitride film is included as the gate insulating film of the transistor, the thickness of the insulating film can be increased. This makes it possible to reduce a decrease in withstand voltage of the transistor and furthermore to increase the withstand voltage, thereby reducing electrostatic discharge damage to the transistor.

### [Metal Oxide]

The metal oxide 108 can be formed using the materials described above.

In the case where the metal oxide 108_1 and the metal oxide 1082 are each In-M-Zn oxide, it is preferable that the atomic ratio of metal elements of a sputtering target used for forming the In-M-Zn oxide satisfy In >M The atomic ratio of metal elements in such a sputtering target is, for example, In:M:Zn=2:1:3, In:M:Zn=3:1:2, In:M:Zn=4:2:4.1, In:M:Zn=5:1:6, In:M:Zn=5:1:7, In:M:Zn=5:1:8, In:M:Zn=6:1:6, or In:M:Zn=5:2:5.

Note that the atomic ratio of metal elements in each of the formed metal oxides 108_1 and 1082 varies from the above atomic ratios of metal elements of the sputtering targets in a range of ±40%. For example, when a sputtering target with an atomic ratio of In to Ga and Zn of 4:2:4.1 is used, the atomic ratio of In to Ga and Zn in the formed metal oxides 108_1 and 108_2 may be 4:2:3 or in the neighborhood of 4:2:3.

The energy gap of each of the metal oxides 108_1 and 108_2 is 2.5 eV or more, preferably 3.0 eV or more. With the use of a metal oxide having such a wide energy gap, the off-state current of the transistor 100A can be reduced.

### [Insulating Film Functioning as Protective Insulating Film]

The insulating film 115 has one or both of a function as a protective insulating film for the transistor 100A and a function of supplying oxygen to the metal oxide 108.

For example, the insulating film 115 preferably contains silicon and one or both of nitrogen and oxygen. The insulating film 115 preferably includes a first layer containing silicon and oxygen and a second layer containing silicon and nitrogen.

The insulating film 115 can be formed by a PAALD method.

Note that when the insulating film 115 is formed by a PAALD method, the formed insulating film 115 has a thickness of greater than or equal to 0.3 nm and less than or equal to 10 nm, preferably greater than or equal to 0.3 nm and less than or equal to 5 nm, further preferably greater than or equal to 0.3 nm and less than or equal to 3 nm. In other words, the insulating film 115 includes a region having a thickness of greater than or equal to 0.3 nm and less than or equal to 10 nm.

Note that in the case where the thickness of the insulating film 115 is in the above range in observing a cross section of a transistor, the insulating film 115 cannot be observed in some cases. The insulating film 115 can be observed by, for example, X-ray photoelectron spectroscopy (XPS). For example, when the insulating film 115 contains silicon and nitrogen, a silicon-nitrogen bond peak is observed. When the insulating film 115 contains silicon and oxygen, a silicon-oxygen bond peak is observed.

The insulating film 115 is preferably an insulating film having a low density of states due to nitrogen oxide (NOₓ, where x is greater than 0 and less than or equal to 2, preferably greater than or equal to 1 and less than or equal to 2; typically NO or NO₂).

Nitrogen oxide forms a level in the insulating film 115, for example. The level is positioned in the energy gap of the metal oxide 108. For example, the density of states due to nitrogen oxide can be formed between the energy of the valence band maximum (Eᵥ_{_}ₒₛ) and the energy of the conduction band minimum (E_{c}_{_}ₒₛ) of the metal oxide 108. Therefore, when nitrogen oxide is diffused to the interface between the insulating film 115 and the metal oxide 108, an electron is in some cases trapped by the level on the insulating film 115 side. As a result, the trapped electron remains in the vicinity of the interface between the insulating film 115 and the metal oxide 108; thus, the threshold voltage of the transistor is shifted in the positive direction.

By using the insulating film having a low density of states due to nitrogen oxide as the insulating film 115, the shift in the threshold voltage of the transistor can be reduced, which leads to a smaller change in the electrical characteristics of the transistor.

Although the variety of films such as the conductive films, the insulating films, and the metal oxides which are described above can be formed by a sputtering method or a PECVD method, such films may be formed by another method, e.g., a thermal chemical vapor deposition (CVD) method. Examples of a thermal CVD method include a metal organic chemical vapor deposition (MOCVD) method and an atomic layer deposition (ALD) method.

A thermal CVD method has an advantage that no defect due to plasma damage is generated since it does not utilize plasma for forming a film. In a thermal CVD method, a source gas is introduced into a chamber, the chamber is set at an atmospheric pressure or a reduced pressure, and a film is deposited on a substrate.

Furthermore, in an ALD method, a source gas is introduced into a chamber, the chamber is set at an atmospheric pressure or a reduced pressure, and a film is deposited on a substrate.

### <1-3. Structure Example 2 of Semiconductor Device>

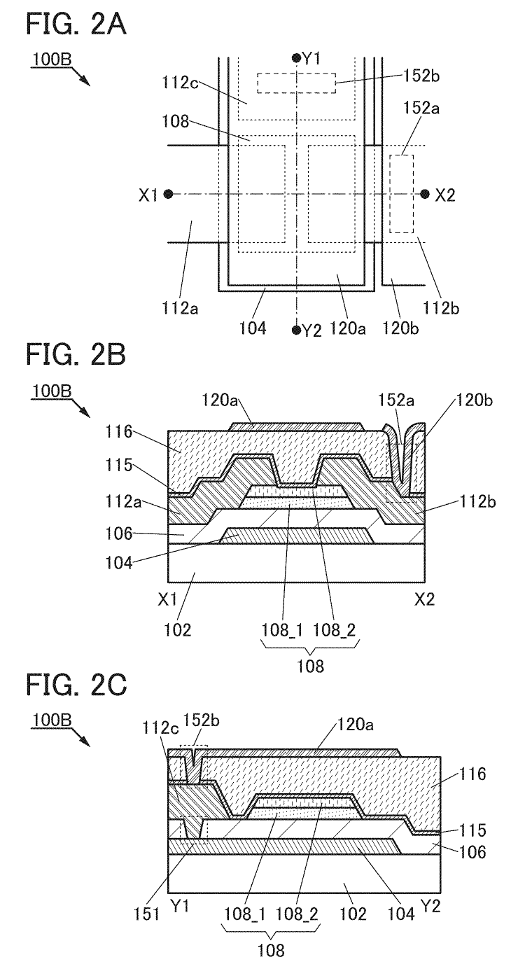

Next, modification examples of the transistor 100A illustrated in FIGS. 1A to 1C are described with reference to FIGS. 2A to 2C.

FIG. 2A is a top view of a transistor 100B that is a semiconductor device of one embodiment of the present invention. FIG. 2B is a cross-sectional view taken along the dashed-dotted line X1-X2 in FIG. 2A, and FIG. 2C is a cross-sectional view taken along the dashed-dotted line Y1-Y2 in FIG. 2A.

The transistor 100B includes the conductive film 104 over the substrate 102, the insulating film 106 over the substrate 102 and the conductive film 104, the metal oxide 108 over the insulating film 106, the conductive film 112a over the metal oxide 108, the conductive film 112b over the metal oxide 108, the insulating film 115 over the metal oxide 108, the conductive film 112a, and the conductive film 112b, an insulating film 116 over the insulating film 115, a conductive film 120a over the insulating film 116, and a conductive film 120b over the insulating film 116.

The insulating film 106 includes an opening 151, and a conductive film 112c that is electrically connected to the conductive film 104 through the opening 151 is formed over the insulating film 106. The insulating films 115 and 116 include an opening 152a which reaches the conductive film 112b and an opening 152b which reaches the conductive film 112c.

Note that in the transistor 100B, the insulating film 106 functions as a first gate insulating film of the transistor 100B, and the insulating films 115 and 116 function as a second gate insulating film of the transistor 100B. In the transistor 100B, the conductive film 104 functions as a first gate electrode, the conductive film 112a functions as a source electrode, and the conductive film 112b functions as a drain electrode. In the transistor 100B, the conductive film 120a functions as a second gate electrode, and the conductive film 120b functions as a pixel electrode of a display device.

As illustrated in FIG. 2C, the conductive film 120a is electrically connected to the conductive film 104 through the openings 152b and 151. Accordingly, the conductive film 104 and the conductive film 120a are supplied with the same potential.

As illustrated in FIG. 2C, the metal oxide 108 faces the conductive film 104 and the conductive film 120a, and is positioned between the two conductive films functioning as the gate electrodes. The length in the channel length direction and the length in the channel width direction of the conductive film 120a are longer than the length in the channel length direction and the length in the channel width direction of the metal oxide 108, respectively. The whole metal oxide 108 is covered with the conductive film 120a with the insulating films 115 and 116 positioned therebetween.

In other words, the conductive film 104 and the conductive film 120a are connected to each other through the openings provided in the insulating films 106, 115, and 116, and each include a region positioned outside a side edge portion of the metal oxide 108.

With this structure, the metal oxide 108 included in the transistor 100B can be electrically surrounded by electric fields of the conductive films 104 and 120a. A device structure of a transistor, like that of the transistor 100B, in which electric fields of a first gate electrode and a second gate electrode electrically surround a metal oxide where a channel region is formed can be referred to as a surrounded channel (S-channel) structure.

Since the transistor 100B has the S-channel structure, an electric field for inducing a channel can be effectively applied to the metal oxide 108 by the conductive film 104 functioning as the first gate electrode; therefore, the current drive capability of the transistor 100B can be improved and high on-state current characteristics can be obtained. Since the on-state current can be increased, the size of the transistor 100B can be reduced. In addition, since the transistor 100B has a structure in which the metal oxide 108 is surrounded by the conductive film 104 functioning as the first gate electrode and the conductive film 120a functioning as the second gate electrode, the mechanical strength of the transistor 100B can be increased.

### <Insulating Film Functioning as Second Gate Insulating Film>

Here, materials that can be used for the insulating film 116 functioning as the second gate insulating film are described. The insulating film 116 is formed using an insulating material, and one or both of an inorganic material and an organic material can be used. As the inorganic material, silicon oxide, silicon oxynitride, silicon nitride oxide, silicon nitride, aluminum oxide, or the like can be used. As the organic material, a heat-resistant resin material such as a polyimide resin, an acrylic resin, a polyimide amide resin, a benzocyclobutene resin, a polyamide resin, or an epoxy resin can be used. The insulating film 116 is preferably formed using the organic material such as an acrylic resin because the insulating film 116 with increased planarity and high productivity can be provided.

For the conductive films 120a and 120b, materials similar to those described as the materials of the above-described conductive films 104, 112a, and 112b can be used. In particular, oxide conductive films (OC) are preferable as the conductive films 120a and 120b. When the conductive films 120a and 120b are formed using an oxide conductive film, oxygen can be added to the insulating films 115 and 116.

The other components of the transistor 100B are similar to those of the transistor 100A described above and have similar effects.

### <1-4. Structure Example 3 of Semiconductor Device>

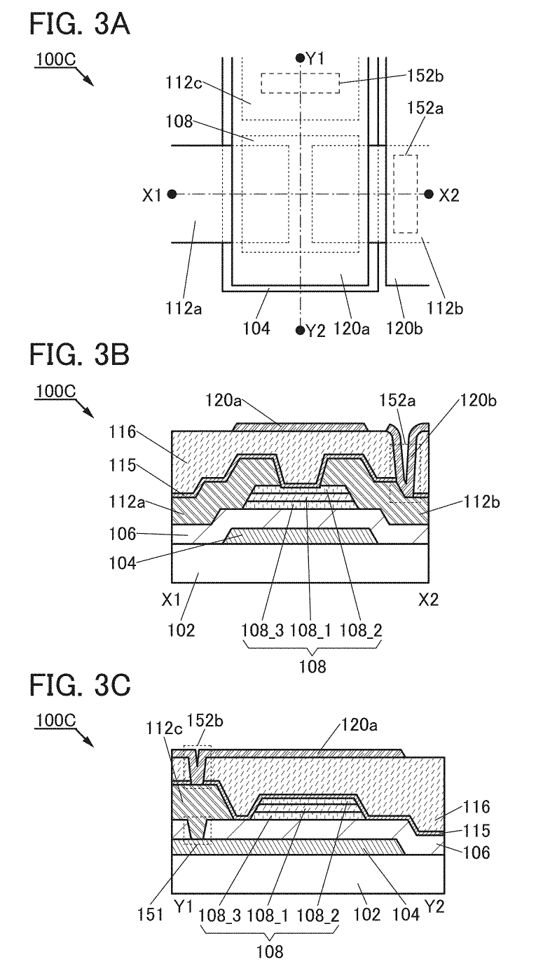

Next, modification examples of the transistor 100B illustrated in FIGS. 2A to 2C are described with reference to FIGS. 3A to 3C.

FIG. 3A is a top view of a transistor 100C that is a semiconductor device of one embodiment of the present invention. FIG. 3B is a cross-sectional view taken along the dashed-dotted line X1-X2 in FIG. 3A, and FIG. 3C is a cross-sectional view taken along the dashed-dotted line Y1-Y2 in FIG. 3A.

The transistor 100C is different from the above-described transistor 100B in that the metal oxide 108 has a three-layer structure. The metal oxide 108 included in the transistor 100C includes a metal oxide 108_3 over the insulating film 106, the metal oxide 108_1 over the metal oxide 1083, and the metal oxide 1082 over the metal oxide 108_1.

### <1-5. Band Structure>

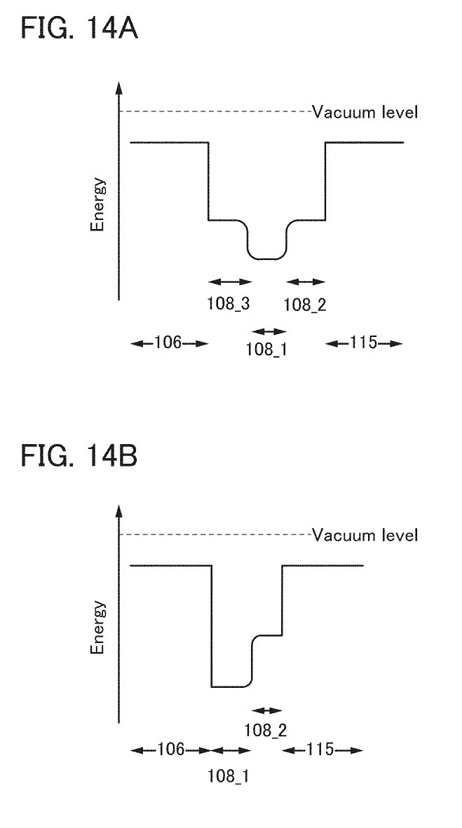

Here, band structures of the metal oxide 108 which has a stacked-layer structure are described with reference to FIGS. 14A and 14B.

FIG. 14A shows an example of a band structure in the thickness direction of a stack including the insulating film 106, the metal oxides 108_1, 108_2, and 108_3, and the insulating film 115. FIG. 14B shows an example of a band structure in the thickness direction of a stack including the insulating film 106, the metal oxides 108_1 and 108_2, and the insulating film 115. For easy understanding, the energy level of the conduction band minimum (E_{c}) of each of the insulating film 106, the metal oxides 108_1, 108_2, and 108_3, and the insulating film 115 is shown in the band structures.

As shown in FIG. 14A, the energy level of the conduction band minimum gradually varies between the metal oxides 108_1, 108_2, and 108_3. As shown in FIG. 14B, the energy level of the conduction band minimum gradually varies between the metal oxides 108_1 and 108_2. In other words, the energy level of the conduction band minimum is continuously varied or continuously connected. To obtain such a band structure, there exists no impurity, which forms a defect state such as a trap center or a recombination center, at the interface between the metal oxides 108_1 and 1082 or the interface between the metal oxides 108_1 and 1083.

To form a continuous junction between the metal oxides 108_1, 108_2, and 108_3, it is necessary to form the films successively without exposure to the air by using a multi-chamber deposition apparatus (sputtering apparatus) provided with a load lock chamber.

With the band structure of FIG. 14A or FIG. 14B, the metal oxide 108_1 serves as a well, and a channel region is formed in the metal oxide 108_1 in the transistor with the stacked-layer structure.

The metal oxides 108_2 and 108_3 are provided, whereby trap states which might be formed in the metal oxide 108_1 can be formed in the metal oxide 108_2 or 108_3. Thus, it is difficult to form the trap states in the metal oxide 108_1.

In addition, the trap states might be more distant from the vacuum level than the energy level of the conduction band minimum (E_{c}) of the metal oxide 108_1 functioning as a channel region, so that electrons are likely to be accumulated in the trap states. When the electrons are accumulated in the trap states, the electrons become negative fixed electric charge, so that the threshold voltage of the transistor is shifted in the positive direction. Therefore, it is preferable that the trap states be closer to the vacuum level than the energy level of the conduction band minimum (E_{c}) of the metal oxide 108_1. Such a structure inhibits accumulation of electrons in the trap states. As a result, the on-state current and the field-effect mobility of the transistor can be increased.

The energy level of the conduction band minimum of each of the metal oxides 1082 and 1083 is closer to the vacuum level than that of the metal oxide 108_1. A typical difference between the energy level of the conduction band minimum of the metal oxide 108_1 and the energy level of the conduction band minimum of each of the metal oxides 1082 and 1083 is 0.15 eV or more or 0.5 eV or more and 2 eV or less or 1 eV or less. That is, the difference between the electron affinity of each of the metal oxides 108_2 and 108_3 and the electron affinity of the metal oxide 108_1 is 0.15 eV or more or 0.5 eV or more and 2 eV or less or 1 eV or less.

In such a structure, the metal oxide 108_1 serves as a main path of a current. In other words, the metal oxide 108_1 serves as a channel region. It is preferable that the metal oxides 108_2 and 108_3 each contain one or more metal elements constituting a part of the metal oxide 108_1 in which a channel region is formed. With such a structure, interface scattering hardly occurs at the interface between the metal oxides 108_1 and 1082 or at the interface between the metal oxides 108_1 and 1083. Thus, the transistor can have high field-effect mobility because the movement of carriers is not hindered at the interface.

It is preferable that the metal oxides 108_2 and 108_3 not have a spinel crystal structure. This is because if the metal oxides 108_2 and 108_3 have a spinel crystal structure, constituent elements of the conductive films 120a and 120b might be diffused into the metal oxide 108_1 at the interface between the spinel crystal structure and another region. Note that each of the metal oxides 108_2 and 108_3 is preferably a CAAC-OS film, in which case a higher blocking property against constituent elements of the conductive films 120a and 120b, for example, copper elements, can be obtained.

The metal oxides 108_2 and 108_3 can be formed using a metal oxide target having an atomic ratio of In:Ga:Zn=1:1:1, In:Ga:Zn=1:3:4, In:Ga:Zn=1:3:6, or the like. Note that the metal oxide target used for the metal oxides 108_2 and 108_3 is not limited to the above target, and a metal oxide target having composition similar to that of the metal oxide target used for the metal oxide 108_1 may be used.

### <1-6. Structure Example 4 of Semiconductor Device>

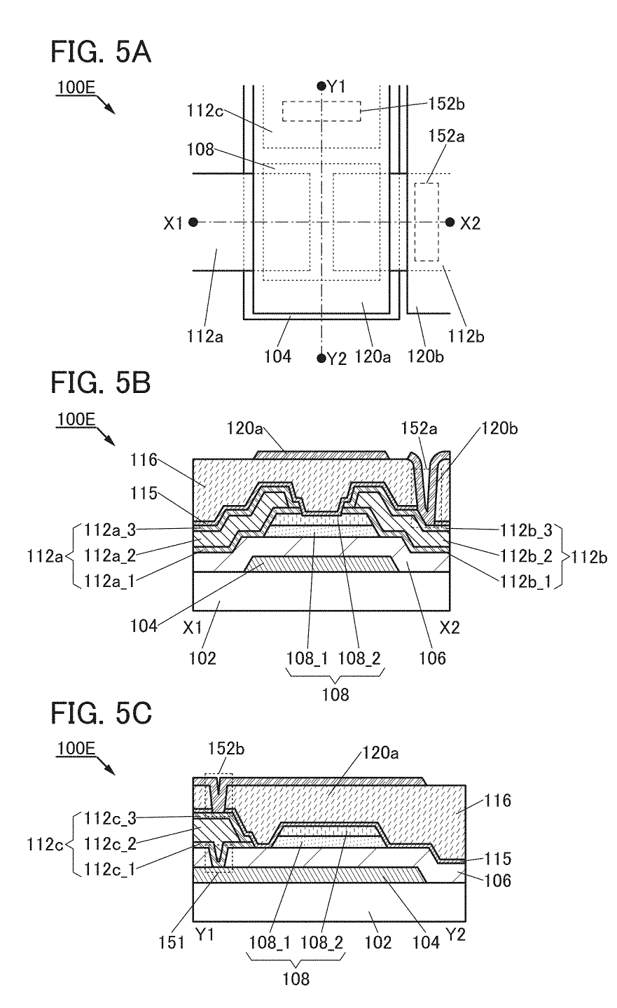

Next, modification examples of the transistor 100B illustrated in FIGS. 2A to 2C are described with reference to FIGS. 4A to 4C, FIGS. 5A to 5C, and FIGS. 6A to 6C.

FIG. 4A is a top view of a transistor 100D that is a semiconductor device of one embodiment of the present invention. FIG. 4B is a cross-sectional view taken along the dashed-dotted line X1-X2 in FIG. 4A, and FIG. 4C is a cross-sectional view taken along the dashed-dotted line Y1-Y2 in FIG. 4A.

The transistor 100D is different from the above-described transistor 100B in that the conductive films 112a, 112b, and 112c each have a three-layer structure.

The conductive film 112a of the transistor 100D includes a conductive film 112a1, a conductive film 112a2 over the conductive film 112a 1, and a conductive film 112a3 over the conductive film 112a2. The conductive film 112b of the transistor 100D includes a conductive film 112b 1, a conductive film 112b 2 over the conductive film 112b 1, and a conductive film 112b3 over the conductive film 112b2. The conductive film 112c of the transistor 100D includes a conductive film 112c 1, a conductive film 112c2 over the conductive film 112c 1, and a conductive film 112c3 over the conductive film 112c2.

For example, it is preferable that the conductive film 112a_1, the conductive film 112b 1, the conductive film 112a 3, and the conductive film 112b3 contain one or more elements selected from titanium, tungsten, tantalum, molybdenum, indium, gallium, tin, and zinc. Furthermore, it is preferable that the conductive film 112a2 and the conductive film 112b_2 contain one or more elements selected from copper, aluminum, and silver.

Specifically, the conductive film 112a1, the conductive film 112b_1, the conductive film 112a 3, and the conductive film 112b_3 can be formed using titanium and the conductive film 112a2 and the conductive film 112b_2 can be formed using copper.

The above structure is preferred because the wiring resistance of the conductive films 112a and 112b can be reduced and diffusion of copper to the metal oxide 108 can be inhibited. The above structure is preferred also because the contact resistance between the conductive film 112b and the conductive film 120b can be low. The other components of the transistor 100D are similar to those of the transistor 100B described above and have similar effects.

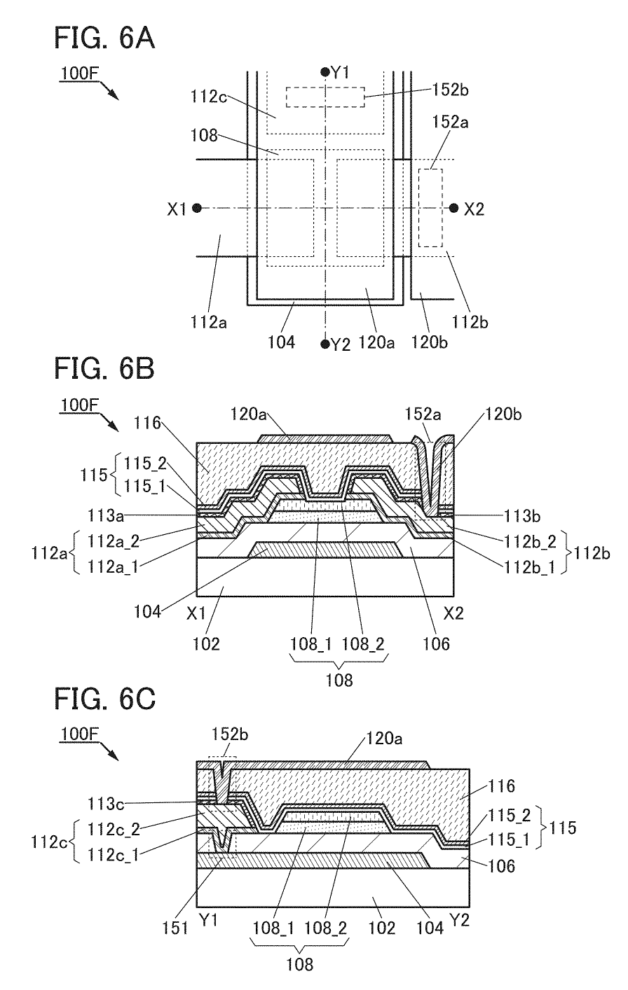

FIG. 5A is a top view of a transistor 100E that is a semiconductor device of one embodiment of the present invention. FIG. 5B is a cross-sectional view taken along the dashed-dotted line X1-X2 in FIG. 5A, and FIG. 5C is a cross-sectional view taken along the dashed-dotted line Y1-Y2 in FIG. 5A.

The transistor 100E is different from the above-described transistor 100B in that the conductive films 112a and 112b each have a three-layer structure. In addition, the transistor 100E is different from the above-described transistor 100D in the shapes of the conductive films 112a and 112b.

The conductive film 112a of the transistor 100E includes the conductive film 112a1, the conductive film 112a2 over the conductive film 112a1, and the conductive film 112a3 over the conductive film 112a2. The conductive film 112b of the transistor 100E includes the conductive film 112b 1, the conductive film 112b_2 over the conductive film 112b 1, and the conductive film 112b3 over the conductive film 112b_2. Note that the conductive film 112a 1, the conductive film 112a 2, the conductive film 112a 3, the conductive film 112b 1, the conductive film 112b 2, and the conductive film 112b_3 can be formed using any of the above-described materials.

An end portion of the conductive film 112a_1 includes a region located outward from an end portion of the conductive film 112a 2. The conductive film 112a3 covers a top surface and a side surface of the conductive film 112a_2 and includes a region that is in contact with the conductive film 112a_1. An end portion of the conductive film 112b_1 includes a region located outward from an end portion of the conductive film 112b_2. The conductive film 112b_3 covers a top surface and a side surface of the conductive film 112b_2 and includes a region that is in contact with the conductive film 112b1.

The above structure is preferred because the wiring resistance of the conductive films 112a and 112b can be reduced and diffusion of copper to the metal oxide 108 can be inhibited. Note that diffusion of copper can be more effectively inhibited in the transistor 100E than in the above-described transistor 100D. The above structure is preferred also because the contact resistance between the conductive film 112b and the conductive film 120b can be low. The other components of the transistor 100E are similar to those of the transistor 100B described above and have similar effects.

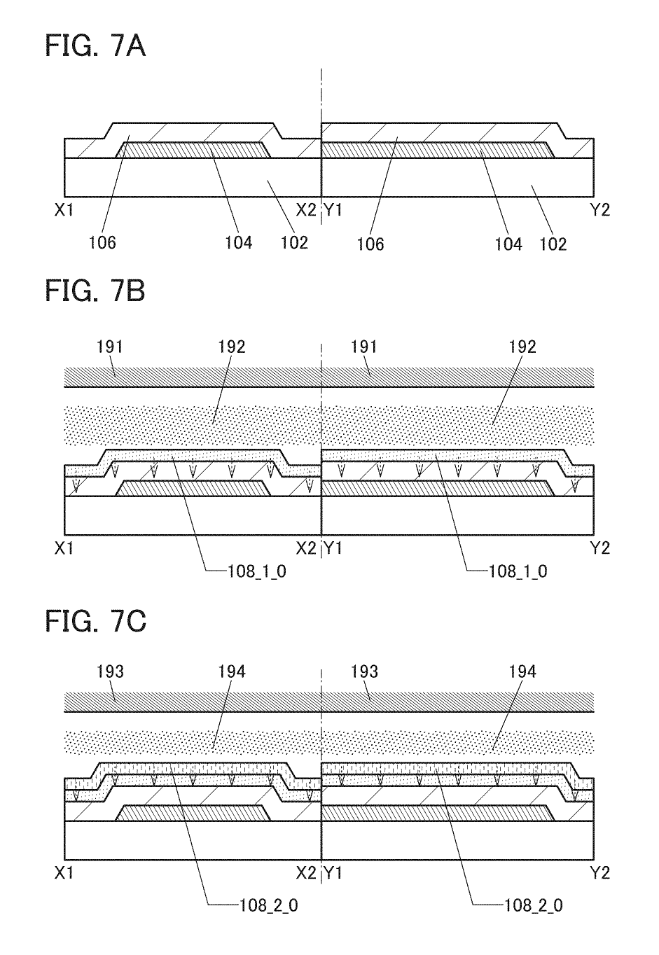

FIG. 6A is a top view of a transistor 100F that is a semiconductor device of one embodiment of the present invention. FIG. 6B is a cross-sectional view taken along the dashed-dotted line X1-X2 in FIG. 6A, and FIG. 6C is a cross-sectional view taken along the dashed-dotted line Y1-Y2 in FIG. 6A.

The transistor 100F is different from the above-described transistor 100B in the structures of the conductive films 112a and 112b and the insulating film 115, and in including an insulating film 113a and an insulating film 113b.

The conductive film 112a of the transistor 100F includes the conductive film 112a1 and the conductive film 112a2 over the conductive film 112a1. The conductive film 112a_2 is covered with the insulating film 113a. The conductive film 112b of the transistor 100F includes the conductive film 112b1 and the conductive film 112b2 over the conductive film 112b1. The conductive film 112b2 is covered with the insulating film 113b.

The insulating films 113a and 113b can be formed by a PAALD method, for example. Specifically, the insulating films 113a and 113b can be formed in the following manner: the conductive films 112a_2 and 112b_2 are formed, and a silane gas or the like is attached to the top surface and the side surface of each of the conductive films 112a2 and 112b_2 by a PAALD method. Note that the insulating films 113a and 113b each include part of constituent elements of the conductive films 112a2 and 112b_2 in some cases. For example, when the conductive films 112a_2 and 112b_2 contain copper, the insulating films 113a and 113b might each contain silicide containing copper.

The insulating film 115 of the transistor 100F includes an insulating film 115_1 and an insulating film 115_2 over the insulating film 115_1. The insulating film 115_1 can be a layer containing silicon and oxygen, and the insulating film 115_2 can be a layer containing silicon and nitrogen. When the insulating film 115_1 is the layer containing silicon and oxygen, oxygen can be supplied to the metal oxide 108. When the insulating film 115_2 is formed over the insulating film 115_1, release of oxygen contained in the insulating film 115_1 to the outside can be suppressed, or entry of impurities from the outside into the insulating film 115_1 and the metal oxide 108 can be suppressed.

The other components of the transistor 100F are similar to those of the transistor 100B described above and have similar effects. The structures of the transistors of this embodiment can be freely combined with each other.

### <1-7. Method for Manufacturing Semiconductor Device>

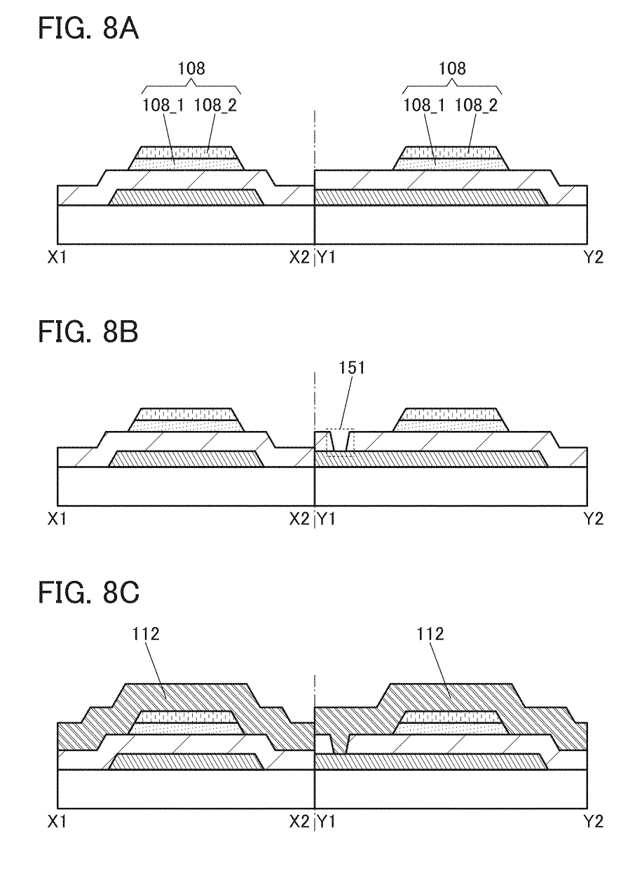

Next, a method for manufacturing the transistor 100B that is a semiconductor device of one embodiment of the present invention is described with reference to FIGS. 7A to 7C, FIGS. 8A to 8C, FIGS. 9A to 9C, FIGS. 10A to 10C, FIGS. 11A and 11B, FIG. 12, and FIG. 13.

FIGS. 7A to 7C, FIGS. 8A to 8C, FIGS. 9A to 9C, FIGS. 10A to 10C, and FIGS. 11A and 11B are cross-sectional views illustrating a method for manufacturing the semiconductor device. In each of FIGS. 7A to 7C, FIGS. 8A to 8C, FIGS. 9A to 9C, FIGS. 10A to 10C, and FIGS. 11A and 11B, the left part is a cross-sectional view in the channel length direction, and the right part is a cross-sectional view in the channel width direction.

First, a conductive film is formed over the substrate 102 and processed through a lithography process and an etching process, whereby the conductive film 104 functioning as the first gate electrode is formed. Then, the insulating film 106 functioning as the first gate insulating film is formed over the conductive film 104 (see FIG. 7A).

In this embodiment, a glass substrate is used as the substrate 102, and as the conductive film 104 functioning as the first gate electrode, a 50-nm-thick titanium film and a 200-nm-thick copper film are each formed by a sputtering method. A 400-nm-thick silicon nitride film and a 50-nm-thick silicon oxynitride film as the insulating film 106 are formed by a PECVD method.

Note that the above-described silicon nitride film has a three-layer structure of a first silicon nitride film, a second silicon nitride film, and a third silicon nitride film. An example of the three-layer structure is as follows.

For example, the first silicon nitride film can be formed to have a thickness of 50 nm under the conditions where silane at a flow rate of 200 sccm, nitrogen at a flow rate of 2000 sccm, and an ammonia gas at a flow rate of 100 sccm are supplied as a source gas to a reaction chamber of a PECVD apparatus, the pressure in the reaction chamber is controlled to 100 Pa, and a power of 2000 W is supplied using a 27.12 MHz high-frequency power source.

The second silicon nitride film can be formed to have a thickness of 300 nm under the conditions where silane at a flow rate of 200 sccm, nitrogen at a flow rate of 2000 sccm, and an ammonia gas at a flow rate of 2000 sccm are supplied as a source gas to the reaction chamber of the PECVD apparatus, the pressure in the reaction chamber is controlled to 100 Pa, and the power of 2000 W is supplied using a 27.12 MHz high-frequency power source.

The third silicon nitride film can be formed to have a thickness of 50 nm under the conditions where silane at a flow rate of 200 sccm and nitrogen at a flow rate of 5000 sccm are supplied as a source gas to the reaction chamber of the PECVD apparatus, the pressure in the reaction chamber is controlled to 100 Pa, and the power of 2000 W is supplied using a 27.12 MHz high-frequency power source.

Note that the first silicon nitride film, the second silicon nitride film, and the third silicon nitride film can each be formed at a substrate temperature of 350° C. or lower.

When the silicon nitride film has the above-described three-layer structure, for example, in the case where a conductive film containing copper is used as the conductive film 104, the following effect can be obtained.

The first silicon nitride film can inhibit diffusion of copper from the conductive film 104. The second silicon nitride film has a function of releasing hydrogen and can improve withstand voltage of the insulating film functioning as a gate insulating film. The third silicon nitride film releases a small amount of hydrogen and can inhibit diffusion of hydrogen released from the second silicon nitride film.

The formation process of the first silicon nitride film and the formation process of the third silicon nitride film may be omitted by performing treatment with a PAALD method before and after the formation of the second silicon nitride film. The treatment with a PAALD method is for example performed as follows: a silane gas is supplied and evacuated and then plasma is generated with a nitrogen gas.

Next, a metal oxide 108_1_0 is formed over the insulating film 106 (see FIG. 7B).

Note that FIG. 7B is a schematic cross-sectional view illustrating the inside of a deposition apparatus when the metal oxide 108_1_0 is formed over the insulating film 106. In FIG. 7B, a sputtering apparatus is used as the deposition apparatus, and a target 191 placed inside the sputtering apparatus and plasma 192 formed under the target 191 are schematically illustrated.

Note that in FIG. 7B, oxygen or excess oxygen added to the insulating film 106 is schematically shown by arrows of broken lines. When an oxygen gas is used in forming the metal oxide 108_1_0, oxygen can be added to the insulating film 106.

The thickness of the metal oxide 108_1_0 is greater than or equal to 1 nm and less than or equal to 50 nm, preferably greater than or equal to 5 nm and less than or equal to 30 nm. The metal oxide 108_1_0 is formed using one or both of an inert gas (typically, an Ar gas) and an oxygen gas. Note that the proportion of the oxygen gas in the deposition gas for forming the metal oxide 108_1_0 (hereinafter also referred to as an oxygen flow rate) is higher than or equal to 0% and lower than 30%, preferably higher than or equal to 5% and lower than or equal to 15%.

When the oxygen flow rate for forming the metal oxide 108_1_0 is set in the above range, the metal oxide 108_1_0 can have lower crystallinity.

In this embodiment, the metal oxide 108_1_0 is formed by a sputtering method using an In—Ga—Zn metal oxide target (In:Ga:Zn=4:2:4.1 in an atomic ratio). The substrate temperature during the formation of the metal oxide 108_1_0 is room temperature, and an argon gas at a flow rate of 180 sccm and an oxygen gas at a flow rate of 20 sccm are used as a deposition gas (percentage of oxygen flow rate: 10%).

Next, a metal oxide 108_2_0 is formed over the metal oxide 108_1_0 (see FIG. 7C).

FIG. 7C is a schematic cross-sectional view illustrating the inside of a deposition apparatus when the metal oxide 108_2_0 is formed over the metal oxide 108_1_0. In FIG. 7C, a sputtering apparatus is used as the deposition apparatus, and a target 193 placed inside the sputtering apparatus and plasma 194 formed under the target 193 are schematically illustrated.

Note that in FIG. 7C, oxygen or excess oxygen added to the metal oxide 108_1_0 is schematically shown by arrows of broken lines. When an oxygen gas is used in forming the metal oxide 108_2_0, oxygen can be added to the metal oxide 108_1_0.

The thickness of the metal oxide 108_2_0 is greater than 10 nm and less than or equal to 100 nm, preferably greater than or equal to 20 nm and less than or equal to 50 nm. When the metal oxide 108_2_0 is formed, plasma discharge is preferably performed in an atmosphere containing an oxygen gas. When plasma discharge is performed in an atmosphere containing an oxygen gas, oxygen is added to the metal oxide 108_1_0 over which the metal oxide 108_2_0 is to be formed. The oxygen flow rate in forming the metal oxide 108_2_0 is higher than or equal to 30% and lower than or equal to 100%, preferably higher than or equal to 50% and lower than or equal to 100%, further preferably higher than or equal to 70% and lower than or equal to 100%.

When the oxygen flow rate for forming the metal oxide 108_2_0 is in the above range, the metal oxide 108_2_0 can have higher crystallinity.

In this embodiment, the metal oxide 108_2_0 is formed by a sputtering method using an In—Ga—Zn metal oxide target (In:Ga:Zn=4:2:4.1 in an atomic ratio). The substrate temperature during the formation of the metal oxide 108_2_0 is room temperature, and an oxygen gas at a flow rate of 200 sccm is used as a deposition gas (percentage of oxygen flow rate: 100%).

As described above, the percentage of oxygen flow rate for forming the metal oxide 108_2_0 is preferably higher than the percentage of oxygen flow rate for forming the metal oxide 108_1_0. In other words, the metal oxide 108_1_0 is preferably formed under a lower oxygen partial pressure than the metal oxide 108_2_0.

When the percentage of oxygen flow rate in forming the metal oxide 108_1_0 is different from that in forming the metal oxide 108_2_0, a layered film having a plurality of kinds of crystallinity can be formed.

The substrate temperature at the time of formation of the metal oxide 108_1_0 and the metal oxide 108_2_0 is set at higher than or equal to room temperature (25° C.) and lower than or equal to 200° C., preferably higher than or equal to room temperature and lower than or equal to 130° C. Setting the substrate temperature in the above range is suitable for the case of using large glass substrates (e.g., the above-described 8th- to 10th-generation glass substrates). Specifically, when the substrate temperature for forming the metal oxide 108_1_0 and the metal oxide 108_2_0 is set at room temperature, bending or distortion of the substrate can be inhibited. Note that in this specification and the like, room temperature also refers to a temperature of the time when heating is not performed intentionally.

In order to increase the crystallinity of the metal oxide 108_2_0, the substrate temperature in forming the metal oxide 108_2_0 is preferably increased (for example, higher than or equal to 100° C. and lower than or equal to 200° C., preferably 130° C.).

In addition, it is more favorable to successively form the metal oxide 108_1_0 and the metal oxide 108_2_0 in a vacuum because impurities can be prevented from being caught at the interfaces.

In addition, increasing the purity of a sputtering gas is necessary. For example, an oxygen gas or an argon gas used for a sputtering gas is highly purified to have a dew point of −40° C. or lower, preferably −80° C. or lower, further preferably −100° C. or lower, still further preferably −120° C. or lower, whereby entry of moisture or the like into the metal oxide can be minimized.

In the case where the metal oxide is formed by a sputtering method, a chamber in a sputtering apparatus is preferably evacuated to be a high vacuum state (to the degree of about 5×10⁻⁷ Pa to 1×10⁻⁴ Pa) with an adsorption vacuum evacuation pump such as a cryopump in order to remove water or the like, which serves as an impurity for the metal oxide, as much as possible. In particular, the partial pressure of gas molecules corresponding to H₂O (gas molecules corresponding to m/z=18) in the chamber in the standby mode of the sputtering apparatus is preferably lower than or equal to 1×10⁻⁴ Pa, further preferably 5×10⁻⁵ Pa.

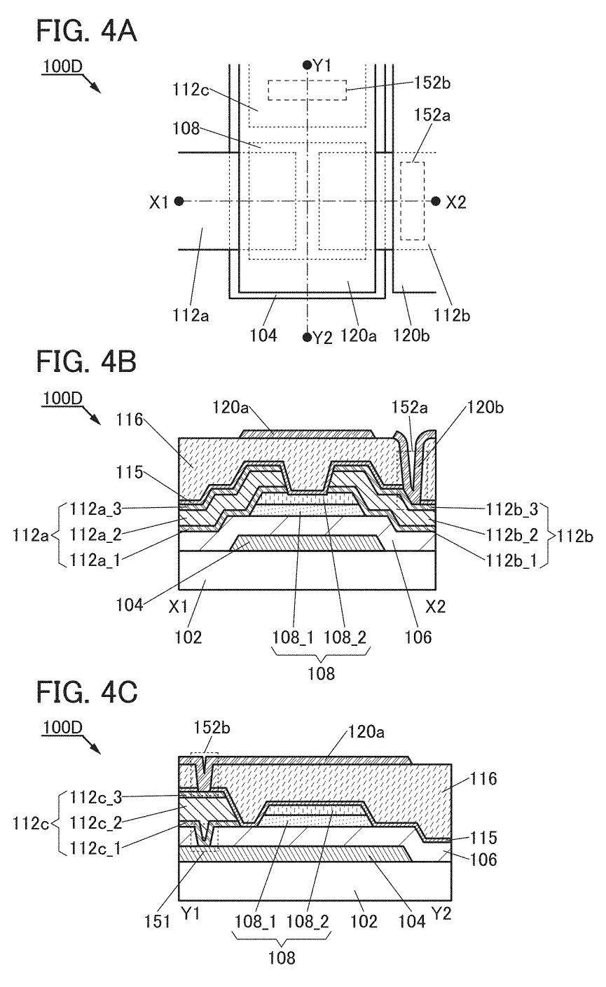

Next, the metal oxide 108_1_0 and the metal oxide 108_2_0 are processed into desired shapes, so that the island-shaped metal oxide 108_1 and the island-shaped metal oxide 1082 are formed. In this embodiment, the metal oxide 108_1 and the metal oxide 108_2 constitute the island-shaped metal oxide 108 (see FIG. 8A).

Heat treatment (hereinafter referred to as first heat treatment) is preferably performed after the metal oxide 108 is formed. By the first heat treatment, hydrogen, water, and the like contained in the metal oxide 108 can be reduced. Note that the heat treatment for the purpose of reducing hydrogen, water, and the like may be performed before the metal oxide 108 is processed into an island shape. Note that the first heat treatment is one kind of treatment for increasing the purity of the metal oxide.

The first heat treatment is performed at a temperature of, for example, higher than or equal to 150° C. and lower than the strain point of the substrate, preferably higher than or equal to 200° C. and lower than or equal to 450° C., further preferably higher than or equal to 250° C. and lower than or equal to 350° C.

Moreover, an electric furnace, an RTA apparatus, or the like can be used for the first heat treatment. With the use of an RTA apparatus, the heat treatment can be performed at a temperature higher than or equal to the strain point of the substrate if the heating time is short. Therefore, the heat treatment time can be shortened. The first heat treatment may be performed under an atmosphere of nitrogen, oxygen, ultra-dry air (air with a water content of 20 ppm or less, preferably 1 ppm or less, further preferably 10 ppb or less), or a rare gas (argon, helium, or the like). The atmosphere of nitrogen, oxygen, ultra-dry air, or a rare gas preferably does not contain hydrogen, water, and the like. Furthermore, after heat treatment is performed under a nitrogen atmosphere or a rare gas atmosphere, heat treatment may be additionally performed in an oxygen atmosphere or an ultra-dry air atmosphere. As a result, hydrogen, water, and the like can be released from the metal oxide and oxygen can be supplied to the metal oxide at the same time. Consequently, the amount of oxygen vacancies in the metal oxide can be reduced.

Next, the opening 151 is formed in the insulating film 106 (see FIG. 8B).

The opening 151 can be formed by one or both of a wet etching method and a dry etching method. Note that the opening 151 reaches the conductive film 104.

Next, a conductive film 112 is formed over the conductive film 104, the insulating film 106, and the metal oxide 108 (see FIG. 8C).

In this embodiment, as the conductive film 112, a 30-nm-thick titanium film and a 200-nm-thick copper film are formed in this order by a sputtering method.

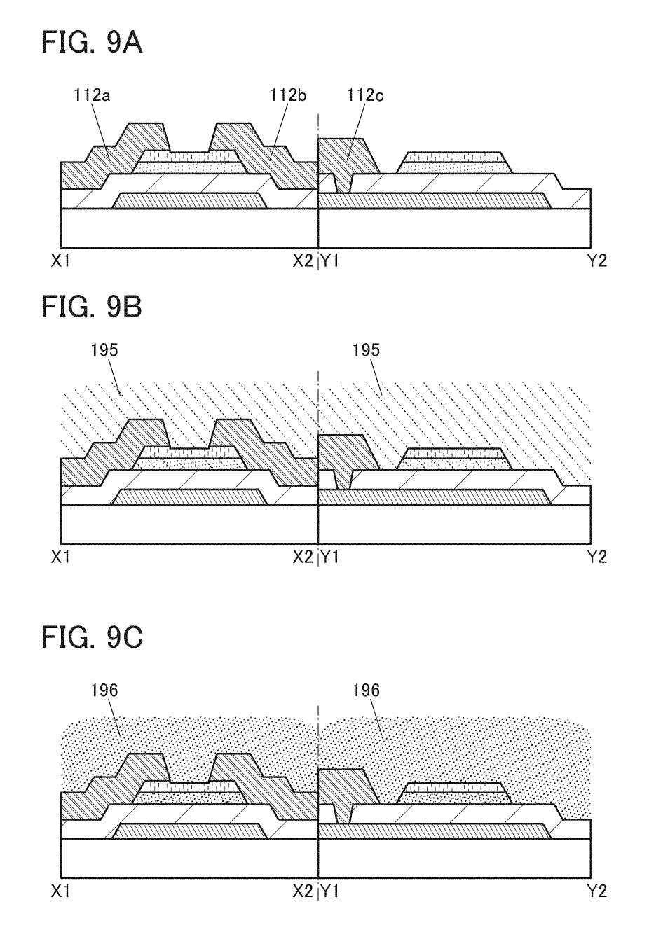

Next, the conductive film 112 is processed into a desired shape, so that the island-shaped conductive film 112a, the island-shaped conductive film 112b, and the island-shaped conductive film 112c are formed (see FIG. 9A).

In this embodiment, the conductive film 112 is processed with a wet etching apparatus. Note that the method for processing the conductive film 112 is not limited to the above-described method, and a dry etching apparatus may be used, for example.

After the conductive films 112a, 112b, and 112c are formed, a surface (on the back channel side) of the metal oxide 108 (specifically, the metal oxide 108_2) may be cleaned. The cleaning may be performed, for example, using a chemical solution such as a phosphoric acid. The cleaning using a chemical solution such as a phosphoric acid can remove impurities (e.g., an element included in the conductive films 112a, 112b, and 112c) attached to the surface of the metal oxide 108_2. Note that the cleaning is not necessarily performed; in some cases, the cleaning is not performed.

In the step of forming the conductive films 112a, 112b, and 112c and/or the cleaning step, the thickness of a region of the metal oxide 108 which is not covered with the conductive films 112a and 112b might be reduced.

Note that in the semiconductor device of one embodiment of the present invention, the region not covered with the conductive films 112a and 112b, i.e., the metal oxide 108_2 is a metal oxide with improved crystallinity. Impurities (in particular, constituent elements used in the conductive films 112a and 112b) are not easily diffused into a metal oxide with high crystallinity. Accordingly, a highly reliable semiconductor device can be provided.

Although FIG. 9A illustrates an example in which the surface of the metal oxide 108 not covered with the conductive films 112a and 112b, i.e., the surface of the metal oxide 108_2 has a depression, one embodiment of the present invention is not limited to this example and the surface of the metal oxide 108 not covered with the conductive films 112a and 112b does not necessarily have a depression.

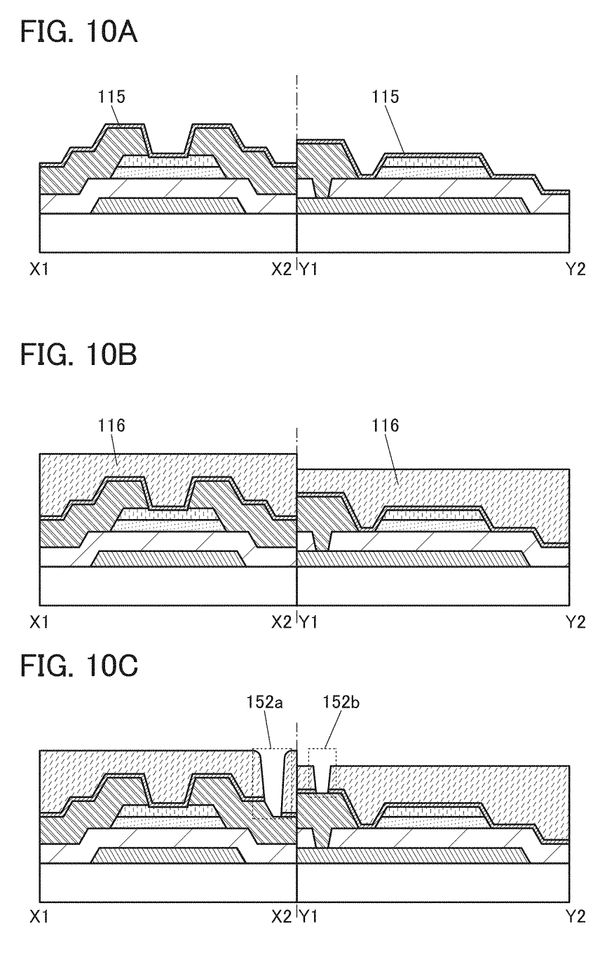

Next, the insulating film 115 is formed over the metal oxide 108 and the conductive films 112a and 112b (see FIGS. 9B and 9C and FIG. 10A).

[Method 1 for forming insulating film (Formation method using PAALD method)]

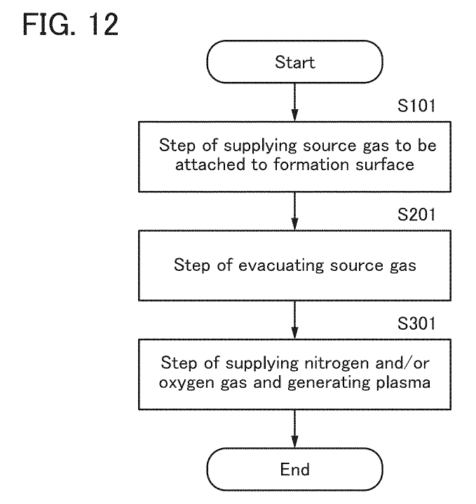

Here, a method for forming the insulating film 115 is described with reference to FIG. 12. FIG. 12 is a flow chart showing the method for forming the insulating film 115.

### [First Step]

The insulating film 115 is preferably formed using a PECVD apparatus. First, the substrate 102 over which the metal oxide 108, the conductive films 112a and 112b, and the like are formed is transferred to a vacuum chamber of the PECVD apparatus. Then, a source gas is supplied to the vacuum chamber, and the source gas is attached to the formation surface, here, the surfaces of the metal oxide 108 and the conductive films 112a and 112b (see FIG. 9B and Step S101 in FIG. 12).

FIG. 9B schematically illustrates the substrate 102 over which the metal oxide 108, the conductive films 112a and 112b, and the like are formed and a state in which a source gas 195 is supplied to the vacuum chamber of the PECVD apparatus. A mixed gas of the source gas 195 and an inert gas (typically, argon, nitrogen, or the like) may be supplied.

The source gas 195 is supplied to the vacuum chamber, whereby the source gas 195 is attached to the surfaces of the metal oxide 108 and the conductive films 112a and 112b at the atomic level. The temperature of the substrate 102 in the vacuum chamber of the PECVD apparatus is higher than or equal to 150° C. and lower than or equal to 450° C., preferably higher than or equal to 200° C. and lower than or equal to 350° C.

In this embodiment, a mixed gas of a silane (SiH₄) gas and a nitrogen gas is supplied to the vacuum chamber under the conditions where the substrate temperature is 220° C., the silane gas is used as the source gas 195, the flow rate of the silane gas is 300 sccm, and the flow rate of the nitrogen gas is 500 sccm. Note that at the time of supply of the mixed gas, the pressure in the vacuum chamber is adjusted to be 40 Pa. After the mixed gas is supplied to the vacuum chamber, the substrate 102 is held for 5 minutes.

### [Second Step]

Next, the source gas is evacuated (see Step S201 in FIG. 12).

In the case where plasma is generated without evacuation of the source gas, the number of particles or the like in the vacuum chamber of the PECVD apparatus is increased in some cases; thus, a step of evacuating the source gas is important.

### [Third Step]

Next, one or both of a nitrogen gas and an oxygen gas are supplied to the vacuum chamber to generate plasma (see FIG. 9C and Step S301 in FIG. 12).

FIG. 9C schematically illustrates the substrate 102 over which the metal oxide 108, the conductive films 112a and 112b, and the like are formed and a state in which one or both of the nitrogen gas and the oxygen gas are supplied to the vacuum chamber of the PECVD apparatus to generate plasma 196.

For example, when the plasma 196 is generated using the nitrogen gas, the silane gas serving as the source gas 195 attached to the surfaces of the metal oxide 108 and the conductive films 112a and 112b reacts with the nitrogen gas, so that a silicon nitride film is deposited on the surfaces of the metal oxide 108 and the conductive films 112a and 112b. Alternatively, when the plasma 196 is generated using the oxygen gas, the silane gas serving as the source gas 195 attached to the surfaces of the metal oxide 108 and the conductive films 112a and 112b reacts with the oxygen gas, so that a silicon oxide film is deposited on the surfaces of the metal oxide 108 and the conductive films 112a and 112b. Alternatively, when the plasma 196 is generated using a mixed gas of a nitrogen gas and an oxygen gas, the silane gas serving as the source gas 195 attached to the surfaces of the metal oxide 108 and the conductive films 112a and 112b reacts with the mixed gas, so that a silicon oxynitride film or a silicon nitride oxide film is deposited on the surfaces of the metal oxide 108 and the conductive films 112a and 112b.

Note that it is preferable that the first to third steps be successively performed in the vacuum chamber of the PECVD apparatus. The first to third steps may be performed more than once. For example, when one cycle consists of the first to third steps, the number of cycles performed is greater than or equal to 1 and less than or equal to 20, preferably greater than or equal to 1 and less than or equal to 10.

The insulating film 115 is formed over the surfaces of the metal oxide 108 and the conductive films 112a and 112b by performing the first to third steps (see FIG. 10A).

The thickness of the insulating film 115 is greater than or equal to 0.1 nm and less than or equal to 10 nm, preferably greater than or equal to 2 nm and less than 10 nm.

### [Method 2 for Forming Insulating Film (Formation Method Using PAALD Method)]

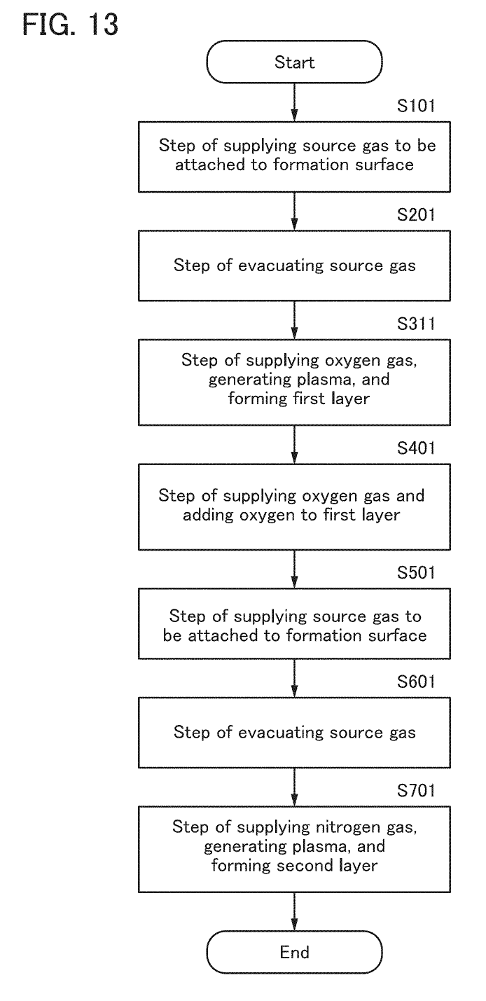

Next, a method for forming the insulating film 115 that is different from the method shown in the flow chart in FIG. 12 is described with reference to FIG. 13. FIG. 13 is a flow chart showing the method for forming the insulating film 115.

### [First Step]

First, the substrate 102 over which the metal oxide 108, the conductive films 112a and 112b, and the like are formed is transferred to a vacuum chamber of a PECVD apparatus. Then, a source gas is supplied to the vacuum chamber, and the source gas is attached to the formation surface, here, the surfaces of the metal oxide 108 and the conductive films 112a and 112b (see Step S101 in FIG. 13).

The source gas 195 is supplied to the vacuum chamber, whereby the source gas 195 is attached to the surfaces of the metal oxide 108 and the conductive films 112a and 112b at the atomic level.

In this embodiment, a mixed gas of a silane (SiH₄) gas and a nitrogen gas is supplied to the vacuum chamber under the conditions where the substrate temperature is 220° C., the silane gas is used as the source gas 195, the flow rate of the silane gas is 300 sccm, and the flow rate of the nitrogen gas is 500 sccm. Note that at the time of supply of the mixed gas, the pressure in the vacuum chamber is adjusted to be 40 Pa. After the mixed gas is supplied to the vacuum chamber, the substrate 102 is held for 5 minutes.

### [Second Step]

Next, the source gas is evacuated (see Step S201 in FIG. 13).

### [Third Step]

Then, an oxygen gas is supplied to the vacuum chamber to generate plasma, so that a first layer is formed (see Step S311 in FIG. 13).

When plasma is generated using an oxygen gas, the silane gas serving as the source gas 195 attached to the surfaces of the metal oxide 108 and the conductive films 112a and 112b reacts with the oxygen gas, so that a silicon oxide film is deposited as the first layer on the surfaces of the metal oxide 108 and the conductive films 112a and 112b.

### [Fourth Step]

Next, an oxygen gas is supplied to the vacuum chamber of the PECVD apparatus to add oxygen to the formed first layer (see Step S401 in FIG. 13).

When oxygen is added to the first layer, the first layer contains oxygen in excess of the stoichiometric composition. The oxygen addition treatment is performed by generating plasma in a gas atmosphere containing oxygen.

### [Fifth Step]

Next, the source gas is supplied to the vacuum chamber of the PECVD apparatus, and the source gas is attached to the formation surface, here, the surface of the formed first layer (see Step S501 in FIG. 13).

The source gas 195 is supplied to the vacuum chamber, whereby the source gas 195 is attached to the surface of the first layer at the atomic level.

In this embodiment, a mixed gas of a silane (SiH₄) gas and a nitrogen gas is supplied to the vacuum chamber under the conditions where the substrate temperature is 220° C., the silane gas is used as the source gas 195, the flow rate of the silane gas is 300 sccm, and the flow rate of the nitrogen gas is 500 sccm. Note that at the time of supply of the mixed gas, the pressure in the vacuum chamber is adjusted to be 40 Pa. After the mixed gas is supplied to the vacuum chamber, the substrate 102 is held for 5 minutes.

### [Sixth Step]

Next, the source gas is evacuated (see Step S601 in FIG. 13).

### [Seventh Step]

Then, a nitrogen gas is supplied to the vacuum chamber to generate plasma, so that a second layer is formed on the first layer (see Step S701 in FIG. 13).

When plasma is generated using a nitrogen gas, the silane gas serving as the source gas 195 attached to the surface of the first layer reacts with the nitrogen gas, so that a silicon nitride film is deposited as the second layer on the surface of the first layer.

The insulating film 115 in which the first layer and the second layer are stacked can be formed by performing the first to seventh steps.

The above is the description of the method for forming the insulating film 115.

Next, the insulating film 116 is formed over the insulating film 115 (see FIG. 10B).

For example, as the insulating film 116, a planarization insulating film such as an acrylic resin film is formed using a spin coater, a slit coater, or the like.

Heat treatment (hereinafter referred to as second heat treatment) is preferably performed after the insulating film 116 is formed. By the second heat treatment, part of oxygen contained in the insulating film 115 can be transferred to the metal oxide 108, so that the amount of oxygen vacancies included in the metal oxide 108 can be reduced.

The temperature of the second heat treatment is typically lower than 400° C., preferably lower than 375° C., further preferably higher than or equal to 150° C. and lower than or equal to 350° C. The second heat treatment may be performed under an atmosphere of nitrogen, oxygen, ultra-dry air (air with a water content of 20 ppm or less, preferably 1 ppm or less, further preferably 10 ppb or less), or a rare gas (argon, helium, or the like). Note that an electric furnace, an RTA apparatus, or the like can be used for the heat treatment, in which it is preferable that hydrogen, water, and the like not be contained in the atmosphere of nitrogen, oxygen, ultra-dry air, or a rare gas.

Next, the openings 152a and 152b are formed in desired regions in the insulating films 115 and 116 (see FIG. 10C).

The openings 152a and 152b can be formed by one or both of a wet etching method and a dry etching method. Note that the opening 152a reaches the conductive film 112b, and the opening 152b reaches the conductive film 112c.

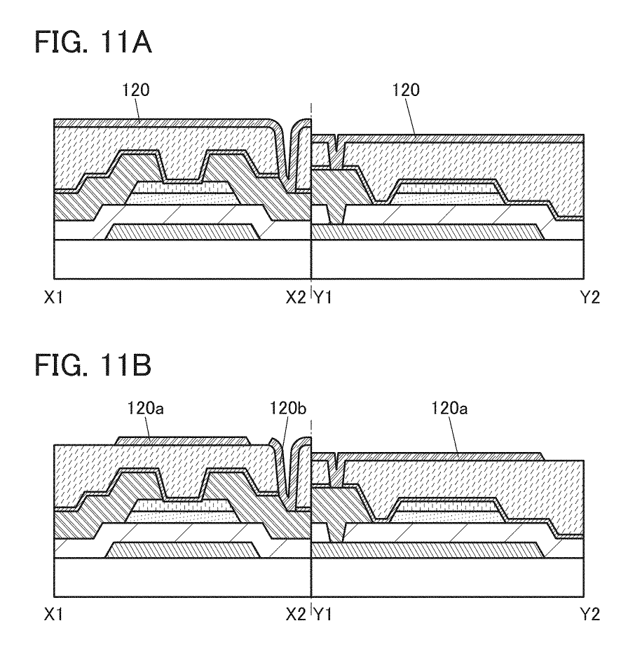

Next, a conductive film 120 is formed over the insulating film 116 to cover the openings 152a and 152b (see FIG. 11A).

As the conductive film 120, an oxide conductive film or the like is formed by a sputtering method. For the oxide conductive film, In—Sn oxide, In—Sn—Si oxide, In—Zn oxide, In—Ga—Zn oxide, or the like can be used.

Next, the conductive film 120 is processed into a desired shape, so that the island-shaped conductive film 120a and the island-shaped conductive film 120b are formed (see FIG. 11B).

In this embodiment, the conductive film 120 is processed with a wet etching apparatus.

After the conductive films 120a and 120b are formed, heat treatment similar to the first heat treatment or the second heat treatment (hereinafter referred to as third heat treatment) may be performed.

By the third heat treatment, oxygen contained in the insulating film 115 moves into the metal oxide 108 to fill the oxygen vacancies in the metal oxide 108.

Through the above process, the transistor 100B illustrated in FIGS. 2A to 2C can be manufactured.

At least part of this embodiment can be implemented in combination with any of the other embodiments described in this specification as appropriate.

### Embodiment 2

In this embodiment, a metal oxide that can be used for a semiconductor film of one embodiment of the present invention is described.

### <2-1. Metal Oxide>

Among metal oxides, an oxide semiconductor is described below.

Oxide semiconductors are classified into a single crystal oxide semiconductor and a non-single-crystal oxide semiconductor. Examples of a non-single-crystal oxide semiconductor include a cloud-aligned composite oxide semiconductor (CAC-OS), a c-axis-aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor. Among the non-single crystal structures, the amorphous structure has the highest density of defect states, whereas the CAAC-OS has the lowest density of defect states.

Note that CAAC refers to an example of a crystal structure, and CAC refers to an example of a function or a material composition. In this specification and the like, a CAC-OS or a CAC metal oxide has a conducting function in a part of the material and has an insulating function in another part of the material; as a whole, the CAC-OS or the CAC metal oxide has a function of a semiconductor. In the case where the CAC-OS or the CAC metal oxide is used in an active layer of a transistor, the conducting function is to allow electrons (or holes) serving as carriers to flow, and the insulating function is to not allow electrons serving as carriers to flow. By the complementary action of the conducting function and the insulating function, the CAC-OS or the CAC metal oxide can have a switching function (on/off function). In the CAC-OS or the CAC-metal oxide, separation of the functions can maximize each function.

In this specification and the like, the CAC-OS or the CAC metal oxide includes conductive regions and insulating regions. The conductive regions have the above-described conducting function, and the insulating regions have the above-described insulating function. In some cases, the conductive regions and the insulating regions in the material are separated at the nanoparticle level. In some cases, the conductive regions and the insulating regions are unevenly distributed in the material. The conductive regions are observed to be coupled in a cloud-like manner with their boundaries blurred, in some cases.

The CAC-OS or the CAC metal oxide includes components having different bandgaps. For example, the CAC-OS or the CAC metal oxide includes a component having a wide gap due to the insulating region and a component having a narrow gap due to the conductive region. In the case of such a composition, carriers mainly flow in the component having a narrow gap. The component having a narrow gap complements the component having a wide gap, and carriers also flow in the component having a wide gap in conjunction with the component having a narrow gap. Therefore, in the case where the above-described CAC-OS or the CAC metal oxide is used in a channel region of a transistor, high current drive capability in the on state of the transistor, that is, high on-state current and high field-effect mobility, can be obtained.

In other words, the CAC-OS or the CAC metal oxide can be called a matrix composite or a metal matrix composite.

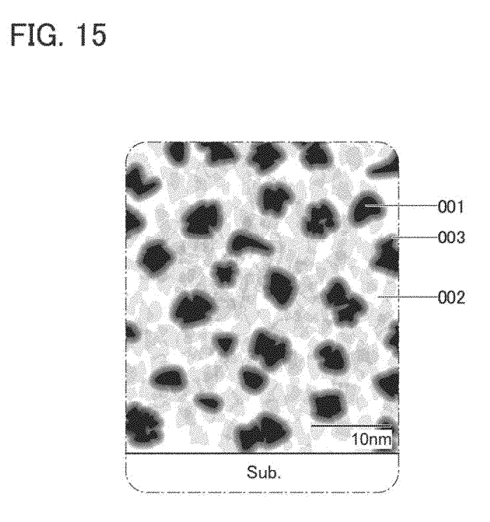

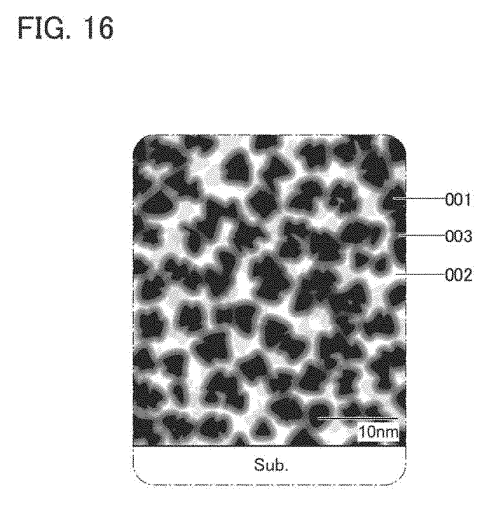

First, a composition of the CAC-OS that is a metal oxide is described with reference to FIG. 15 and FIG. 16. Note that FIG. 15 and FIG. 16 are schematic cross-sectional views each illustrating a concept of the CAC-OS.

### <2-2. Composition of CAC-OS>

For example, in the CAC-OS, as illustrated in FIG. 15, elements included in the metal oxide are unevenly distributed, and regions 001 mainly including an element, regions 002 mainly including another element, and regions 003 mainly including another element are formed. The regions 001, 002, and 003 are mixed to form a mosaic pattern. In other words, the CAC-OS has a composition in which elements included in a metal oxide are unevenly distributed. Materials including unevenly distributed elements each have a size of greater than or equal to 0.5 nm and less than or equal to 10 nm, preferably greater than or equal to 1 nm and less than or equal to 2 nm, or a similar size. Note that in the following description of a metal oxide, a state in which one or more metal elements are unevenly distributed and regions including the metal element(s) are mixed is referred to as a mosaic pattern or a patch-like pattern. The regions each have a size of greater than or equal to 0.5 nm and less than or equal to 10 nm, preferably greater than or equal to 1 nm and less than or equal to 2 nm, or a similar size.

Note that a metal oxide preferably contains at least indium. In particular, indium and zinc are preferably contained. In addition, an element M (M is gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, or magnesium) may be contained.

For example, an In-M-Zn oxide with the CAC-OS composition has a composition in which materials are separated into indium oxide (InO_{X1}, where X1 is a real number greater than 0) or indium zinc oxide (In_{X2}Zn_{Y2}O_{Z2}, where X2, Y2, and Z2 are real numbers greater than 0), and an oxide of the element M (MO_{X3}, where X3 is a real number greater than 0) or an M-Zn oxide (M_{X4}Zn_{Y4}O_{Z4}, where X4, Y4, and Z4 are real numbers greater than 0), and a mosaic pattern is formed. InO_{X1} or In_{X2}Zn_{Y2}O_{Z2} forming the mosaic pattern is distributed in the film. This composition is also referred to as a cloud-like composition.

Let a concept in FIG. 15 illustrate an In-M-Zn oxide with the CAC-OS composition. In that case, the region 001 mainly includes MO_{X3}, the region 002 mainly includes In_{X2}Zn_{Y2}O_{Z2} or InO_{X1}, and the region 003 includes at least Zn. Surrounding portions of the region mainly including MO_{X3}, the region mainly including In_{X2}Zn_{Y2}O_{Z2} or InO_{X1}, and the region including at least Zn are unclear (blurred), so that the boundaries are not clearly observed in some cases.

In other words, the In-M-Zn oxide with the CAC-OS composition is a metal oxide in which the region mainly including MO_{X3} and the region mainly including In_{X2}Zn_{Y2}O_{Z2} or InO_{X1} are mixed. Accordingly, the metal oxide is referred to as a composite metal oxide in some cases. Note that in this specification, for example, when the atomic ratio of In to the element M in the region 002 is greater than the atomic ratio of In to the element M in the region 001, the region 002 has higher In concentration than the region 001.

Note that in the metal oxide with the CAC-OS composition, a stacked-layer structure including two or more films with different compositions is not included. For example, a two-layer structure of a film including In as a main component and a film including Ga as a main component is not included.

Specifically, of the CAC-OS, an In—Ga—Zn oxide with the CAC-OS composition (such an In—Ga—Zn oxide may be particularly referred to as CAC-IGZO) is described. In an In—Ga—Zn oxide with the CAC-OS composition, materials are separated into InO_{X1} or In_{X2}Zn_{Y2}O_{Z2}, and gallium oxide (GaO_{X5}, where X5 is a real number greater than 0) or gallium zinc oxide (Ga_{X6}Zn_{Y6}O_{Z6}, where X6, Y6, and Z6 are real numbers greater than 0), for example, and a mosaic pattern is formed. InO_{X1} or In_{X2}Zn_{Y2}O_{Z2} forming the mosaic pattern is a cloud-like metal oxide.

In other words, an In—Ga—Zn oxide with the CAC-OS composition is a composite metal oxide having a composition in which a region including GaO_{X5} as a main component and a region including In_{X2}Zn_{Y2}O_{Z2} or InO_{X1} as a main component are mixed. Surrounding portions of the region including GaO_{X5} as a main component and the region including In_{X2}Zn_{Y2}O_{Z2} or InO_{X1} as a main component are unclear (blurred), so that boundaries are not clearly observed in some cases.

Note that the sizes of the regions 001 to 003 can be obtained by EDX mapping. For example, the diameter of the region 001 is greater than or equal to 0.5 nm and less than or equal to 10 nm, or greater than or equal to 1 nm and less than or equal to 2 nm in the EDX mapping image of a cross-sectional photograph in some cases. The density of an element in a main component is gradually lowered from the central portion of the region toward the surrounding portion. For example, when the number (abundance) of atoms of an element countable in an EDX mapping image gradually changes from the central portion toward the surrounding portion, the surrounding portion of the region is unclear (blurred) in the EDX mapping of the cross-sectional photograph. For example, from the central portion toward the surrounding portion in the region including GaO_{X5} as a main component, the number of Ga atoms gradually reduces and the numbers of Zn atoms gradually increases, so that the region including Ga_{X6}Zn_{Y6}O_{Z6} as a main component gradually appears. Accordingly, the surrounding portion of the region including GaO_{X5} as a main component is unclear (blurred) in the EDX mapping image.

Note that a compound including In, Ga, Zn, and O is also known as IGZO.

Typical examples of IGZO include a crystalline compound represented by InGaO₃(ZnO)ₘ₁ (m1 is a natural number) and a crystalline compound represented by In₍₁₊ₓ₀₎Ga₍₁₋ₓ₀₎O₃(ZnO)ₘ₀ (−1≦x0≦1; m0 is a given number).

The above crystalline compounds have a single crystal structure, a polycrystalline structure, or a c-axis-aligned crystalline (CAAC) structure. Note that the CAAC structure is a layered crystal structure in which a plurality of IGZO nanocrystals have c-axis alignment and are connected in the a-b plane direction without alignment.

In this specification and the like, CAC-IGZO can be defined as a metal oxide including In, Ga, Zn, and O in the state where a plurality of regions including Ga as a main component and a plurality of regions including In as a main component are each dispersed randomly in a mosaic pattern.

For example, in the conceptual view in FIG. 15, the region 001 corresponds to the region including Ga as a main component, the region 002 corresponds to the region including In as a main component, and the region 003 corresponds to a region including zinc. Note that the region including Ga as a main component and the region including In as a main component may each be referred to as a nanoparticle. The diameter of the nanoparticle is greater than or equal to 0.5 nm and less than or equal to 10 nm, typically greater than or equal to 1 nm and less than or equal to 2 nm. Surrounding portions of the nanoparticles are unclear (blurred), so that boundaries are not clearly observed in some cases.

FIG. 16 illustrates a modification example of the conceptual view in FIG. 15. As illustrated in FIG. 16, the region 001, the region 002, and the region 003 have different shapes or densities depending on conditions for forming the metal oxide in some cases.

The crystallinity of an In—Ga—Zn oxide with the CAC-OS composition can be analyzed by electron diffraction. For example, a ring-like region with high luminance is observed in an electron diffraction pattern image. Furthermore, a plurality of spots are observed in the ring-like region in some cases.

As described above, the In—Ga—Zn oxide with the CAC-OS composition has a structure different from that of an IGZO compound in which metal elements are evenly distributed, and has characteristics different from those of the IGZO compound. That is, in the In—Ga—Zn oxide with the CAC-OS composition, regions including GaO_{X5} or the like as a main component and regions including In_{X2}Zn_{Y2}O_{Z2} or InO_{X1} as a main component are separated to form a mosaic pattern.

In the case where aluminum, silicon, boron, yttrium, tin, copper, vanadium, beryllium, titanium, iron, nickel, germanium, zirconium, molybdenum, lanthanum, cerium, neodymium, hafnium, tantalum, tungsten, or magnesium is contained instead of gallium in a CAC-OS, nanoparticle regions including the metal element as a main component are observed in part of the CAC-OS and nanoparticle regions including In as a main component are observed in part thereof, and these nanoparticle regions are randomly dispersed to form a mosaic pattern in the CAC-OS.

The conductivity of a region including In_{X2}Zn_{Y2}O_{Z2} or InO_{X1} as a main component is higher than that of a region including GaO_{X5} or the like as a main component. In other words, in the region with high conductivity, the proportion of In is relatively high. In the following description, the region with a relatively high proportion of In may be referred to as an In-rich region for convenience. That is, when carriers flow through regions including In_{X2}Zn_{Y2}O_{Z2} or InO_{X1} as a main component, conductivity is exhibited. Accordingly, when regions including In_{X2}Zn_{Y2}O_{Z2} or InO_{X1} as a main component are distributed in a metal oxide like a cloud, high field-effect mobility (μ) can be achieved.

In contrast, the insulating property of a region including GaO_{X5} or the like as a main component is higher than that of a region including In_{X2}Zn_{Y2}O_{Z2} or InO_{X1} as a main component. In other words, in the region with a high insulating property, the proportion of Ga is relatively high. In the following description, the region with a relatively high proportion of Ga may be referred to as a Ga-rich region for convenience. That is, when regions including GaO_{X5} or the like as a main component are distributed in a metal oxide, leakage current can be suppressed and favorable switching operation can be achieved.

Accordingly, when an In—Ga—Zn oxide with the CAC-OS composition is used for a semiconductor element, the insulating property derived from GaO_{X5} or the like and the conductivity derived from In_{X2}Zn_{Y2}O_{Z2} or InO_{X1} complement each other, whereby high on-state current (Iₒₙ), high field-effect mobility (4 and low off-state current (I_{off}) can be achieved.

A semiconductor element including an In—Ga—Zn oxide with the CAC-OS composition has high reliability. Thus, an In—Ga—Zn oxide with the CAC-OS composition is suitably used in a variety of semiconductor devices typified by a display.

At least part of this embodiment can be implemented in combination with any of the other embodiments described in this specification as appropriate.

### Embodiment 3

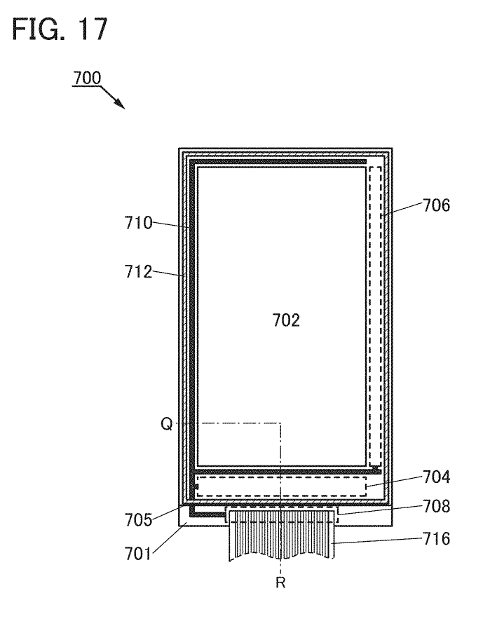

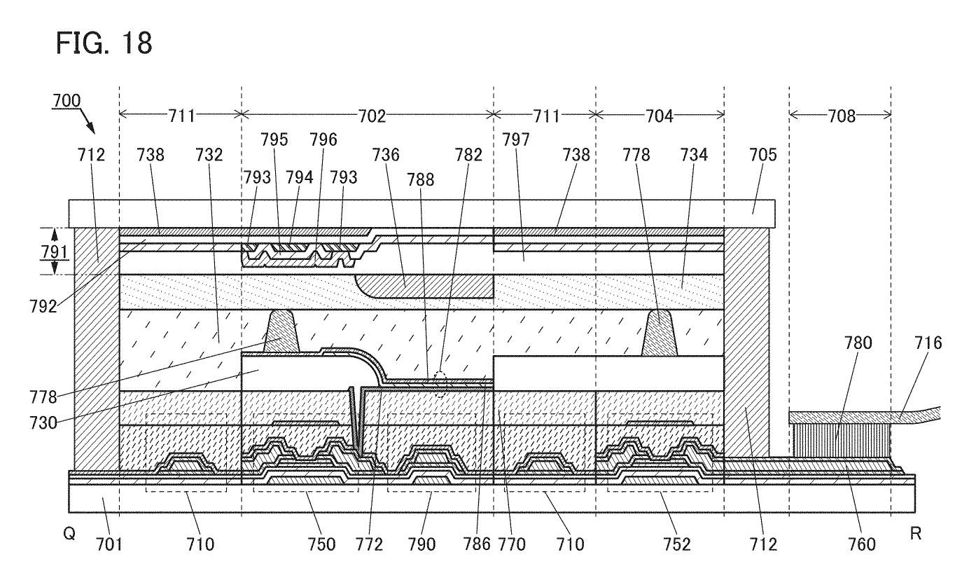

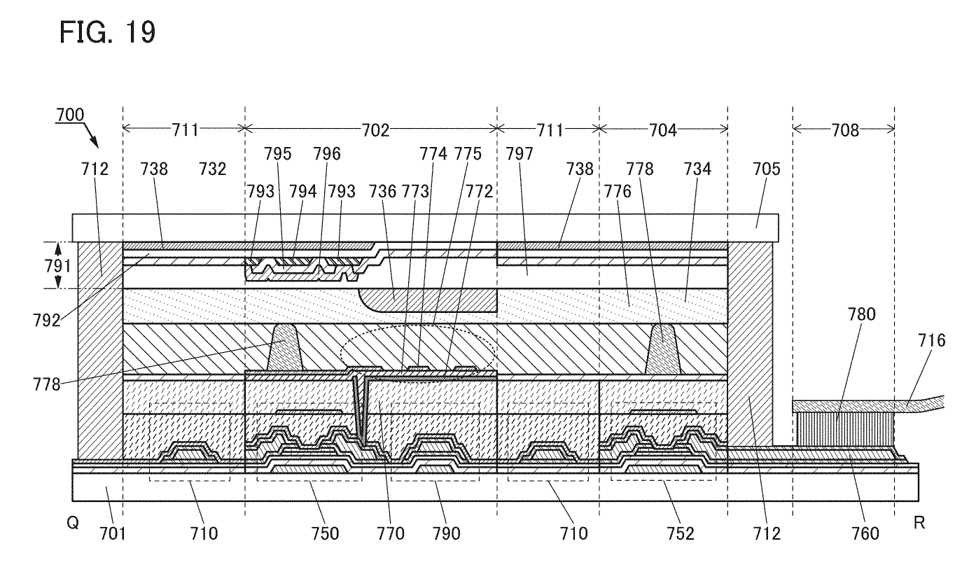

In this embodiment, an example of a display device that includes any of the transistors described in the above embodiment is described below with reference to FIG. 17, FIG. 18, and FIG. 19.

FIG. 17 is a top view of an example of a display device. A display device 700 illustrated in FIG. 17 includes a pixel portion 702 provided over a first substrate 701, a source driver circuit portion 704 and a gate driver circuit portion 706 that are provided over the first substrate 701, a sealant 712 provided to surround the pixel portion 702, the source driver circuit portion 704, and the gate driver circuit portion 706, and a second substrate 705 provided to face the first substrate 701. The first substrate 701 and the second substrate 705 are sealed with the sealant 712. That is, the pixel portion 702, the source driver circuit portion 704, and the gate driver circuit portion 706 are sealed with the first substrate 701, the sealant 712, and the second substrate 705. Although not illustrated in FIG. 17, a display element is provided between the first substrate 701 and the second substrate 705.

In the display device 700, a flexible printed circuit (FPC) terminal portion 708 electrically connected to the pixel portion 702, the source driver circuit portion 704, and the gate driver circuit portion 706 is provided in a region different from the region that is over the first substrate 701 and surrounded by the sealant 712. Furthermore, an FPC 716 is connected to the FPC terminal portion 708, and a variety of signals and the like are supplied to the pixel portion 702, the source driver circuit portion 704, and the gate driver circuit portion 706 through the FPC 716. Furthermore, a signal line 710 is connected to the pixel portion 702, the source driver circuit portion 704, the gate driver circuit portion 706, and the FPC terminal portion 708. Through the signal line 710, a variety of signals and the like are supplied from the FPC 716 to the pixel portion 702, the source driver circuit portion 704, the gate driver circuit portion 706, and the FPC terminal portion 708.

A plurality of gate driver circuit portions 706 may be provided in the display device 700. An example of the display device 700 in which the source driver circuit portion 704 and the gate driver circuit portion 706 are formed over the first substrate 701 where the pixel portion 702 is also formed is described; however, the structure is not limited thereto. For example, only the gate driver circuit portion 706 may be formed over the first substrate 701 or only the source driver circuit portion 704 may be formed over the first substrate 701. In that case, a substrate over which a source driver circuit, a gate driver circuit, or the like is formed (e.g., a driver circuit board formed using a single-crystal semiconductor film or a polycrystalline semiconductor film) may be formed on the first substrate 701. Note that there is no particular limitation on the method for connecting the separately prepared driver circuit substrate, and a chip on glass (COG) method, a wire bonding method, or the like can be used.

The pixel portion 702, the source driver circuit portion 704, and the gate driver circuit portion 706 included in the display device 700 include a plurality of transistors. As the plurality of transistors, any of the transistors that are the semiconductor devices of embodiments of the present invention can be used.

The display device 700 can include any of a variety of elements. Examples of the elements include electroluminescent (EL) element (e.g., an EL element containing organic and inorganic materials, an organic EL element, an inorganic EL element, or an LED), a light-emitting transistor element (a transistor that emits light depending on current), an electron emitter, a liquid crystal element, an electronic ink display, an electrophoretic element, an electrowetting element, a plasma display panel (PDP), a micro electro mechanical systems (MEMS) display (e.g., a grating light valve (GLV), a digital micromirror device (DMD), a digital micro shutter (DMS) element, or an interferometric modulator display (IMOD) element), and a piezoelectric ceramic display.

Examples of a display device including an EL element include an EL display. Examples of a display device including an electron emitter include a field emission display (FED) and an SED-type flat panel display (SED: surface-conduction electron-emitter display). Examples of a display device including a liquid crystal element include a liquid crystal display (e.g., a transmissive liquid crystal display, a transflective liquid crystal display, a reflective liquid crystal display, a direct-view liquid crystal display, or a projection liquid crystal display). Examples of a display device including an electronic ink display or an electrophoretic element include electronic paper. In the case of a transflective liquid crystal display or a reflective liquid crystal display, some or all of pixel electrodes function as reflective electrodes. For example, some or all of pixel electrodes are formed to contain aluminum, silver, or the like. In such a case, a memory circuit such as an SRAM can be provided under the reflective electrodes. Thus, the power consumption can be further reduced.

As a display system of the display device 700, a progressive system, an interlace system, or the like can be employed. Furthermore, color elements controlled in pixels at the time of color display are not limited to three colors: R, G, and B (R, G, and B correspond to red, green, and blue, respectively). For example, four pixels of the R pixel, the G pixel, the B pixel, and a W (white) pixel may be included. Alternatively, a color element may be composed of two colors among R, G, and B as in PenTile layout. The two colors may differ among color elements. Alternatively, one or more colors of yellow, cyan, magenta, and the like may be added to RGB. Note that the size of a display region may differ between dots of the color elements. One embodiment of the disclosed invention is not limited to a color display device; the disclosed invention can also be applied to a monochrome display device.

A coloring layer (also referred to as a color filter) may be used to obtain a full-color display device in which white light (W) is used for a backlight (e.g., an organic EL element, an inorganic EL element, an LED, or a fluorescent lamp). For example, a red (R) coloring layer, a green (G) coloring layer, a blue (B) coloring layer, and a yellow (Y) coloring layer can be combined as appropriate. With the use of the coloring layer, higher color reproducibility can be obtained as compared with the case without the coloring layer. In that case, by providing a region with a coloring layer and a region without a coloring layer, white light in the region without the coloring layer may be directly utilized for display. By partly providing the region without the coloring layer, a decrease in the luminance of a bright image due to the coloring layer can be suppressed, and approximately 20% to 30% of power consumption can be reduced in some cases. In the case where full-color display is performed using a self-luminous element such as an organic EL element or an inorganic EL element, elements may emit light in their respective colors R, G, B, Y, and W. By using a self-luminous element, power consumption can be further reduced as compared with the case of using a coloring layer in some cases.

As a coloring system, any of the following systems may be used: the above-described color filter system in which part of white light is converted into red light, green light, and blue light through color filters; a three-color system in which red light, green light, and blue light are used; and a color conversion system or a quantum dot system in which part of blue light is converted into red light or green light.

In this embodiment, a structure including an EL element as a display element and a structure including a liquid crystal element as a display element are described with reference to FIG. 18 and FIG. 19. FIG. 18 is a cross-sectional view taken along the dashed-dotted line Q-R in FIG. 17 and illustrates the structure including an EL element as a display element. FIG. 19 is a cross-sectional view taken along the dashed-dotted line Q-R in FIG. 17 and illustrates the structure including a liquid crystal element as a display element.

Common portions between FIG. 18 and FIG. 19 are described first, and then different portions are described.

### <3-1. Common Portions in Display Devices>

The display device 700 illustrated in FIG. 18 and FIG. 19 includes a lead wiring portion 711, the pixel portion 702, the source driver circuit portion 704, and the FPC terminal portion 708. The lead wiring portion 711 includes the signal line 710. The pixel portion 702 includes a transistor 750 and a capacitor 790. The source driver circuit portion 704 includes a transistor 752.

The transistor 750 and the transistor 752 each have a structure similar to that of the transistor 100E described above. Note that the transistor 750 and the transistor 752 may each have the structure of any of the other transistors described in the above embodiments.

The transistor used in this embodiment includes a metal oxide that is highly purified and in which formation of oxygen vacancies is suppressed. The transistor can have low off-state current. Accordingly, an electrical signal such as an image signal can be held for a longer time, and a writing interval can be set longer in an on state. Accordingly, the frequency of refresh operation can be reduced, which suppresses power consumption.

In addition, the transistor used in this embodiment can have relatively high field-effect mobility and thus is capable of high speed operation. For example, in a liquid crystal display device that includes such a transistor capable of high-speed operation, a switching transistor in a pixel portion and a driver transistor in a driver circuit portion can be formed over one substrate. That is, no additional semiconductor device formed using a silicon wafer or the like is needed as a driver circuit; therefore, the number of components of the semiconductor device can be reduced. In addition, by using the transistor capable of high-speed operation in the pixel portion, a high-quality image can be provided.

The capacitor 790 includes a lower electrode and an upper electrode. The lower electrode is formed through a step of processing a conductive film to be a conductive film functioning as a first gate electrode of the transistor 750. The upper electrode is formed through a step of processing a conductive film to be a conductive film functioning as source and drain electrodes of the transistor 750. Between the lower electrode and the upper electrode, an insulating film formed through a step of forming an insulating film to be an insulating film functioning as a first gate insulating film of the transistor 750 is provided. That is, the capacitor 790 has a stacked-layer structure in which an insulating film functioning as a dielectric film is positioned between the pair of electrodes.

In FIG. 18 and FIG. 19, a planarization insulating film 770 is provided over the transistor 750, the transistor 752, and the capacitor 790.

The planarization insulating film 770 can be formed using a heat-resistant organic material such as a polyimide resin, an acrylic resin, a polyimide amide resin, a benzocyclobutene resin, a polyamide resin, or an epoxy resin. Note that the planarization insulating film 770 may be formed by stacking a plurality of insulating films formed from these materials. Alternatively, a structure without the planarization insulating film 770 may be employed.

Although FIG. 18 and FIG. 19 each illustrate an example in which the transistor 750 included in the pixel portion 702 and the transistor 752 included in the source driver circuit portion 704 have the same structure, one embodiment of the present invention is not limited thereto. For example, the pixel portion 702 and the source driver circuit portion 704 may include different transistors. Specifically, a structure in which a staggered transistor is used in the pixel portion 702 and the inverted-staggered transistor described in Embodiment 1 is used in the source driver circuit portion 704, or a structure in which the inverted-staggered transistor described in Embodiment 1 is used in the pixel portion 702 and a staggered transistor is used in the source driver circuit portion 704 may be employed. Note that the term “source driver circuit portion 704” can be replaced by the term “gate driver circuit portion”.

The signal line 710 is formed through the same process as the conductive films functioning as source electrodes and drain electrodes of the transistors 750 and 752. In the case where the signal line 710 is formed using a material containing a copper element, signal delay or the like due to wiring resistance is reduced, which enables display on a large screen.

The FPC terminal portion 708 includes a connection electrode 760, an anisotropic conductive film 780, and the FPC 716. Note that the connection electrode 760 is formed through the same process as the conductive films functioning as source electrodes and drain electrodes of the transistors 750 and 752. The connection electrode 760 is electrically connected to a terminal included in the FPC 716 through the anisotropic conductive film 780.

For example, a glass substrate can be used as the first substrate 701 and the second substrate 705. A flexible substrate may be used as the first substrate 701 and the second substrate 705. Examples of the flexible substrate include a plastic substrate.

A structure body 778 is provided between the first substrate 701 and the second substrate 705. The structure body 778 is a columnar spacer obtained by selective etching of an insulating film and provided to control the distance (cell gap) between the first substrate 701 and the second substrate 705. Alternatively, a spherical spacer may also be used as the structure body 778.

A light-blocking film 738 functioning as a black matrix, a coloring film 736 functioning as a color filter, and an insulating film 734 in contact with the light-blocking film 738 and the coloring film 736 are provided on the second substrate 705 side.

### <3-2. Structure Example of Input/Output Device of Display Device>

In the display device 700 illustrated in FIG. 18 and FIG. 19, a touch panel 791 as an input/output device is provided. Note that the display device 700 that does not include the touch panel 791 may also be used.

The touch panel 791 illustrated in FIG. 18 and FIG. 19 is what is called an in-cell touch panel provided between the second substrate 705 and the coloring film 736. The touch panel 791 is formed on the second substrate 705 side before the light-blocking film 738 and the coloring film 736 are formed.

The touch panel 791 includes the light-blocking film 738, an insulating film 792, an electrode 793, an electrode 794, an insulating film 795, an electrode 796, and an insulating film 797. A change in the mutual capacitance between the electrode 793 and the electrode 794 can be sensed when an object such as a finger or a stylus approaches, for example.

A portion in which the electrode 793 intersects with the electrode 794 is illustrated in the upper portion of the transistor 750 in FIG. 18 and FIG. 19. Through openings in the insulating film 795, the electrode 796 is electrically connected to the two electrodes 793 between which the electrode 794 is positioned. Note that a structure in which a region where the electrode 796 is provided is provided in the pixel portion 702 is illustrated in FIG. 18 and FIG. 19 as an example; however, one embodiment of the present invention is not limited thereto. For example, the region where the electrode 796 is provided may be provided in the source driver circuit portion 704.

The electrodes 793 and 794 are provided in a region overlapping with the light-blocking film 738. As illustrated in FIG. 18, it is preferable that the electrode 793 do not overlap with a light-emitting element 782. As illustrated in FIG. 19, it is preferable that the electrode 793 do not overlap with a liquid crystal element 775. In other words, the electrode 793 includes an opening in a region overlapping with the light-emitting element 782 and the liquid crystal element 775. That is, the electrode 793 has a mesh shape. With such a structure, the electrode 793 does not block light emitted from the light-emitting element 782, or alternatively the electrode 793 does not block light transmitted through the liquid crystal element 775. Thus, since luminance is hardly reduced even when the touch panel 791 is provided, a display device with high visibility and low power consumption can be obtained. Note that the electrode 794 can have a structure similar to that of the electrode 793.

Since the electrodes 793 and 794 do not overlap with the light-emitting element 782, the electrodes 793 and 794 can be formed using a metal material with low visible light transmittance. Furthermore, since the electrodes 793 and 794 do not overlap with the liquid crystal element 775, the electrodes 793 and 794 can be formed using a metal material with low visible light transmittance.

Thus, as compared with the case of using an oxide material whose transmittance of visible light is high, resistance of the electrodes 793 and 794 can be reduced, whereby sensitivity of the sensor of the touch panel can be increased.

For example, a conductive nanowire may be used for the electrodes 793, 794, and 796. The nanowire may have a mean diameter of greater than or equal to 1 nm and less than or equal to 100 nm, preferably greater than or equal to 5 nm and less than or equal to 50 nm, further preferably greater than or equal to 5 nm and less than or equal to 25 nm. As the nanowire, a carbon nanotube or a metal nanowire such as an Ag nanowire, a Cu nanowire, or an Al nanowire may be used. For example, in the case where an Ag nanowire is used for any one of or all of the electrodes 793, 794, and 796, the transmittance of visible light can be greater than or equal to 89% and the sheet resistance can be greater than or equal to 40 Ω/square and less than or equal to 100 Ω/square.

Although the structure of the in-cell touch panel is illustrated in FIG. 18 and FIG. 19, one embodiment of the present invention is not limited thereto. For example, a touch panel formed over the display device 700, what is called an on-cell touch panel, or a touch panel attached to the display device 700, what is called an out-cell touch panel may be used. In this manner, the display device 700 of one embodiment of the present invention can be combined with various types of touch panels.

### <3-3. Display Device Including Light-Emitting Element>

The display device 700 illustrated in FIG. 18 includes the light-emitting element 782. The light-emitting element 782 includes a conductive film 772, an EL layer 786, and a conductive film 788. The display device 700 illustrated in FIG. 18 can display an image by utilizing light emission from the EL layer 786 of the light-emitting element 782. Note that the EL layer 786 contains an organic compound or an inorganic compound such as a quantum dot.

Examples of a material that can be used for an organic compound include a fluorescent material and a phosphorescent material. Examples of a material that can be used for a quantum dot include a colloidal quantum dot material, an alloyed quantum dot material, a core-shell quantum dot material, and a core quantum dot material. A material containing elements belonging to Groups 12 and 16, elements belonging to Groups 13 and 15, or elements belonging to Groups 14 and 16, may be used. Alternatively, a quantum dot material containing an element such as cadmium (Cd), selenium (Se), zinc (Zn), sulfur (S), phosphorus (P), indium (In), tellurium (Te), lead (Pb), gallium (Ga), arsenic (As), or aluminum (Al) may be used.

In the display device 700 in FIG. 18, an insulating film 730 is provided over the planarization insulating film 770 and the conductive film 772. The insulating film 730 covers part of the conductive film 772. Note that the light-emitting element 782 has a top-emission structure. Thus, the conductive film 788 has a light-transmitting property and transmits light emitted from the EL layer 786. Although the top-emission structure is described as an example in this embodiment, the structure is not limited thereto. For example, a bottom-emission structure in which light is emitted to the conductive film 772 side or a dual-emission structure in which light is emitted to both the conductive film 772 side and the conductive film 788 side may be employed.

The coloring film 736 is provided to overlap with the light-emitting element 782, and the light-blocking film 738 is provided in the lead wiring portion 711 and the source driver circuit portion 704 to overlap with the insulating film 730. The coloring film 736 and the light-blocking film 738 are covered with the insulating film 734. A space between the light-emitting element 782 and the insulating film 734 is filled with a sealing film 732. The structure of the display device 700 is not limited to the example in FIG. 18, in which the coloring film 736 is provided. For example, a structure without the coloring film 736 may also be employed in the case where the EL layer 786 is formed by separate coloring.

### <3-4. Structure Example of Display Device Including Liquid Crystal Element>

The display device 700 illustrated in FIG. 19 includes the liquid crystal element 775. The liquid crystal element 775 includes the conductive film 772, an insulating film 773, a conductive film 774, and a liquid crystal layer 776. The conductive film 774 functions as a common electrode, and an electric field generated between the conductive film 772 and the conductive film 774 through the insulating film 773 can control the alignment state in the liquid crystal layer 776. The display device 700 in FIG. 19 can display an image in such a manner that transmission or non-transmission of light is controlled by the alignment state in the liquid crystal layer 776 which is changed depending on a voltage applied between the conductive film 772 and the conductive film 774.

The conductive film 772 is electrically connected to the conductive film functioning as the source electrode or the drain electrode of the transistor 750. The conductive film 772 is formed over the planarization insulating film 770 and functions as a pixel electrode, that is, one electrode of the display element.

A conductive film that transmits visible light or a conductive film that reflects visible light can be used as the conductive film 772. For example, a material containing an element selected from indium (In), zinc (Zn), and tin (Sn) is preferably used for the conductive film that transmits visible light. For example, a material containing aluminum or silver is preferably used for the conductive film that reflects visible light. In this embodiment, the conductive film that reflects visible light is used as the conductive film 772.

Although FIG. 19 illustrates an example in which the conductive film 772 is connected to the conductive film functioning as the drain electrode of the transistor 750, one embodiment of the present invention is not limited to this example. For example, the conductive film 772 may be electrically connected to the conductive film functioning as the drain electrode of the transistor 750 through a conductive film functioning as a connection electrode.

Although not illustrated in FIG. 19, an alignment film may be provided in contact with the liquid crystal layer 776. Although not illustrated in FIG. 19, an optical member (optical substrate) and the like, such as a polarizing member, a retardation member, or an anti-reflection member, may be provided as appropriate. For example, circular polarization may be employed by using a polarizing substrate and a retardation substrate. In addition, a backlight, a side light, or the like may be used as a light source.

In the case where a liquid crystal element is used as the display element, a thermotropic liquid crystal, a low-molecular liquid crystal, a high-molecular liquid crystal, a polymer-dispersed liquid crystal, a ferroelectric liquid crystal, an anti-ferroelectric liquid crystal, or the like can be used. Such a liquid crystal material exhibits a cholesteric phase, a smectic phase, a cubic phase, a chiral nematic phase, an isotropic phase, or the like depending on conditions.

In the case where a horizontal electric field mode is employed, a liquid crystal exhibiting a blue phase for which an alignment film is unnecessary may be used. The blue phase is one of liquid crystal phases, which is generated just before a cholesteric phase changes into an isotropic phase while the temperature of a cholesteric liquid crystal is increased. Since the blue phase appears only in a narrow temperature range, a liquid crystal composition in which several weight percent or more of a chiral material is mixed is used for the liquid crystal layer in order to improve the temperature range. The liquid crystal composition containing a liquid crystal exhibiting a blue phase and a chiral material has a short response time and optical isotropy, which eliminates the need for an alignment process. An alignment film does not need to be provided, and thus, rubbing treatment is not necessary; accordingly, electrostatic discharge damage caused by the rubbing treatment can be prevented, and defects and damage of a liquid crystal display device in the manufacturing process can be reduced. Moreover, the liquid crystal material that exhibits a blue phase has small viewing angle dependence.

In the case where a liquid crystal element is used as the display element, a twisted nematic (TN) mode, an in-plane-switching (IPS) mode, a fringe field switching (FFS) mode, an axially symmetric aligned micro-cell (ASM) mode, an optical compensated birefringence (OCB) mode, a ferroelectric liquid crystal (FLC) mode, an antiferroelectric liquid crystal (AFLC) mode, or the like can be used.

Furthermore, a normally black liquid crystal display device such as a vertical alignment (VA) mode transmissive liquid crystal display device may also be used. There are some examples of a vertical alignment mode; for example, a multi-domain vertical alignment (MVA) mode, a patterned vertical alignment (PVA) mode, or an ASV mode can be employed.

At least part of this embodiment can be implemented in combination with any of the other embodiments described in this specification as appropriate.

### Embodiment 4

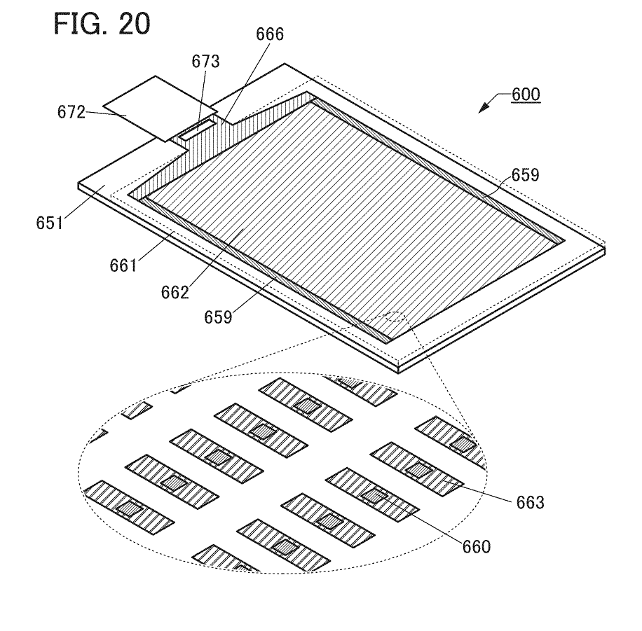

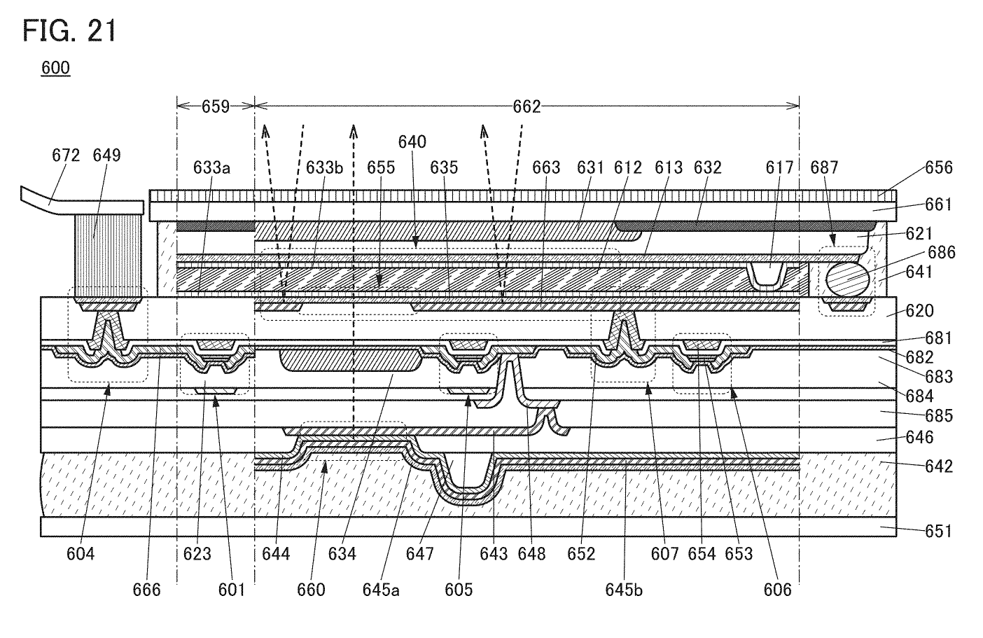

In this embodiment, an example of a display panel that can be used for a display portion or the like in a display device including the semiconductor device of one embodiment of the present invention is described with reference to FIG. 20 and FIG. 21. The display panel described below as an example includes both a reflective liquid crystal element and a light-emitting element and can display an image in both the transmissive mode and the reflective mode.

### <4-1. Structure Example of Display Panel>

FIG. 20 is a schematic perspective view illustrating a display panel 600 of one embodiment of the present invention. In the display panel 600, a substrate 651 and a substrate 661 are attached to each other. In FIG. 20, the substrate 661 is denoted by a dashed line.

The display panel 600 includes a display portion 662, a circuit 659, a wiring 666, and the like. The substrate 651 is provided with the circuit 659, the wiring 666, a conductive film 663 which serves as a pixel electrode, and the like. In FIG. 20, an IC 673 and an FPC 672 are mounted on the substrate 651. Thus, the structure illustrated in FIG. 20 can be referred to as a display module including the display panel 600, the FPC 672, and the IC 673.

As the circuit 659, for example, a circuit functioning as a scan line driver circuit can be used.

The wiring 666 has a function of supplying a signal or electric power to the display portion or the circuit 659. The signal or electric power is input to the wiring 666 from the outside through the FPC 672 or from the IC 673.

FIG. 20 illustrates an example in which the IC 673 is provided on the substrate 651 by a chip on glass (COG) method or the like. As the IC 673, an IC functioning as a scan line driver circuit, a signal line driver circuit, or the like can be used. Note that it is possible that the IC 673 is not provided when, for example, the display panel 600 includes circuits serving as a scan line driver circuit and a signal line driver circuit and when the circuits serving as a scan line driver circuit and a signal line driver circuit are provided outside and a signal for driving the display panel 600 is input through the FPC 672. Alternatively, the IC 673 may be mounted on the FPC 672 by a chip on film (COF) method or the like.

FIG. 20 also illustrates an enlarged view of part of the display portion 662. The conductive films 663 included in a plurality of display elements are arranged in a matrix in the display portion 662. The conductive film 663 has a function of reflecting visible light and serves as a reflective electrode of a liquid crystal element 640 described later.

As illustrated in FIG. 20, the conductive film 663 includes an opening. A light-emitting element 660 is positioned closer to the substrate 651 than the conductive film 663 is. Light is emitted from the light-emitting element 660 to the substrate 661 side through the opening in the conductive film 663.

### <4-2. Cross-Sectional Structure Example>

FIG. 21 illustrates an example of cross sections of part of a region including the FPC 672, part of a region including the circuit 659, and part of a region including the display portion 662 of the display panel illustrated in FIG. 20.

The display panel includes an insulating film 620 between the substrates 651 and 661. The display panel also includes the light-emitting element 660, a transistor 601, a transistor 605, a transistor 606, a coloring layer 634, and the like between the substrate 651 and the insulating film 620. Furthermore, the display panel includes the liquid crystal element 640, a coloring layer 631, and the like between the insulating film 620 and the substrate 661. The substrate 661 and the insulating film 620 are bonded with an adhesive layer 641. The substrate 651 and the insulating film 620 are bonded with an adhesive layer 642.

The transistor 606 is electrically connected to the liquid crystal element 640 and the transistor 605 is electrically connected to the light-emitting element 660. Since the transistors 605 and 606 are formed on a surface of the insulating film 620 which is on the substrate 651 side, the transistors 605 and 606 can be formed through the same process.

The substrate 661 is provided with the coloring layer 631, a light-blocking film 632, an insulating film 621, a conductive film 613 serving as a common electrode of the liquid crystal element 640, an alignment film 633b, an insulating film 617, and the like. The insulating film 617 serves as a spacer for holding a cell gap of the liquid crystal element 640.

Insulating layers such as an insulating film 681, an insulating film 682, an insulating film 683, an insulating film 684, and an insulating film 685 are provided on the substrate 651 side of the insulating film 620. Part of the insulating film 681 functions as a gate insulating layer of each transistor. The insulating films 682, 683, and 684 are provided to cover each transistor. The insulating film 685 is provided to cover the insulating film 684. The insulating films 684 and 685 each function as a planarization layer. Note that an example in which the three insulating layers, the insulating films 682, 683, and 684, are provided to cover the transistors and the like is described here; however, one embodiment of the present invention is not limited to this example, and four or more insulating layers, a single insulating layer, or two insulating layers may be provided. The insulating film 684 functioning as a planarization layer is not necessarily provided.

The transistors 601, 605, and 606 each include a conductive film 654 part of which functions as a gate, a conductive film 652 part of which functions as a source or a drain, and a semiconductor film 653. Here, a plurality of layers obtained by processing the same conductive film are shown with the same hatching pattern.

The liquid crystal element 640 is a reflective liquid crystal element. The liquid crystal element 640 has a stacked structure of a conductive film 635, a liquid crystal layer 612, and the conductive film 613. In addition, the conductive film 663 which reflects visible light is provided in contact with the surface of the conductive film 635 that faces the substrate 651. The conductive film 663 includes an opening 655. The conductive films 635 and 613 contain a material transmitting visible light. In addition, an alignment film 633a is provided between the liquid crystal layer 612 and the conductive film 635 and the alignment film 633b is provided between the liquid crystal layer 612 and the conductive film 613. A polarizing plate 656 is provided on an outer surface of the substrate 661.

In the liquid crystal element 640, the conductive film 663 has a function of reflecting visible light and the conductive film 613 has a function of transmitting visible light. Light entering from the substrate 661 side is polarized by the polarizing plate 656, passes through the conductive film 613 and the liquid crystal layer 612, and is reflected by the conductive film 663. Then, the light passes through the liquid crystal layer 612 and the conductive film 613 again and reaches the polarizing plate 656. In this case, alignment of the liquid crystal is controlled with a voltage that is applied between the conductive film 613 and the conductive film 663, and thus optical modulation of light can be controlled. That is, the intensity of light emitted through the polarizing plate 656 can be controlled. Light excluding light in a particular wavelength region is absorbed by the coloring layer 631, and thus, emitted light is red light, for example.

The light-emitting element 660 is a bottom-emission light-emitting element. The light-emitting element 660 has a structure in which a conductive film 643, an EL layer 644, and a conductive film 645b are stacked in this order from the insulating film 620 side. In addition, a conductive film 645a is provided to cover the conductive film 645b. The conductive film 645b contains a material reflecting visible light, and the conductive films 643 and 645a contain a material transmitting visible light. Light is emitted from the light-emitting element 660 to the substrate 661 side through the coloring layer 634, the insulating film 620, the opening 655, the conductive film 613, and the like.

Here, as illustrated in FIG. 21, the conductive film 635 transmitting visible light is preferably provided for the opening 655. Accordingly, the liquid crystal is aligned in a region overlapping with the opening 655 as well as in the other regions, in which case an alignment defect of the liquid crystal is prevented from being generated in the boundary portion of these regions and undesired light leakage can be suppressed.

As the polarizing plate 656 provided on an outer surface of the substrate 661, a linear polarizing plate or a circularly polarizing plate can be used. An example of a circularly polarizing plate is a stack including a linear polarizing plate and a quarter-wave retardation plate. Such a structure can reduce reflection of external light. The cell gap, alignment, drive voltage, and the like of the liquid crystal element used as the liquid crystal element 640 are controlled depending on the kind of the polarizing plate so that desirable contrast is obtained.

In addition, an insulating film 647 is provided on an insulating film 646 covering an end portion of the conductive film 643. The insulating film 647 has a function as a spacer for preventing the insulating film 620 and the substrate 651 from being closer to each other than necessary. In the case where the EL layer 644 or the conductive film 645a is formed using a blocking mask (metal mask), the insulating film 647 may have a function of preventing the blocking mask from being in contact with a surface on which the EL layer 644 or the conductive film 645a is formed. Note that the insulating film 647 is not necessarily provided.

One of a source and a drain of the transistor 605 is electrically connected to the conductive film 643 of the light-emitting element 660 through a conductive film 648.

One of a source and a drain of the transistor 606 is electrically connected to the conductive film 663 through a connection portion 607. The conductive films 663 and 635 are in contact with and electrically connected to each other. Here, in the connection portion 607, the conductive layers provided on both surfaces of the insulating film 620 are connected to each other through an opening in the insulating film 620.

A connection portion 604 is provided in a region where the substrates 651 and 661 do not overlap with each other. The connection portion 604 is electrically connected to the FPC 672 through a connection layer 649. The connection portion 604 has a structure similar to that of the connection portion 607. On the top surface of the connection portion 604, a conductive layer obtained by processing the same conductive film as the conductive film 635 is exposed. Thus, the connection portion 604 and the FPC 672 can be electrically connected to each other through the connection layer 649.

A connection portion 687 is provided in part of a region where the adhesive layer 641 is provided. In the connection portion 687, the conductive layer obtained by processing the same conductive film as the conductive film 635 is electrically connected to part of the conductive film 613 with a connector 686. Accordingly, a signal or a potential input from the FPC 672 connected to the substrate 651 side can be supplied to the conductive film 613 formed on the substrate 661 side through the connection portion 687.

As the connector 686, a conductive particle can be used, for example. As the conductive particle, a particle of an organic resin, silica, or the like coated with a metal material can be used. It is preferable to use nickel or gold as the metal material because contact resistance can be decreased. It is also preferable to use a particle coated with layers of two or more kinds of metal materials, such as a particle coated with nickel and further with gold. As the connector 686, a material capable of elastic deformation or plastic deformation is preferably used. As illustrated in FIG. 21, the connector 686 which is the conductive particle has a shape that is vertically crushed in some cases. With the crushed shape, the contact area between the connector 686 and a conductive layer electrically connected to the connector 686 can be increased, thereby reducing contact resistance and suppressing the generation of problems such as disconnection.

The connector 686 is preferably provided so as to be covered with the adhesive layer 641. For example, the connectors 686 are dispersed in the adhesive layer 641 before curing of the adhesive layer 641.

FIG. 21 illustrates an example of the circuit 659 in which the transistor 601 is provided.

The structure in which the semiconductor film 653 where a channel is formed is provided between two gates is used as an example of the transistors 601 and 605 in

FIG. 21. One gate is formed using the conductive film 654 and the other gate is formed using a conductive film 623 overlapping with the semiconductor film 653 with the insulating film 682 provided therebetween. Such a structure enables control of threshold voltages of transistors. In that case, the two gates may be connected to each other and supplied with the same signal to operate the transistors. Such transistors can have higher field-effect mobility and thus have higher on-state current than other transistors. Consequently, a circuit capable of high-speed operation can be obtained. Furthermore, the area occupied by a circuit portion can be reduced. The use of the transistor having high on-state current can reduce signal delay in wirings and can reduce display unevenness even in a display panel in which the number of wirings is increased because of increase in size or definition.

Note that the transistor included in the circuit 659 and the transistor included in the display portion 662 may have the same structure. A plurality of transistors included in the circuit 659 may have the same structure or different structures. A plurality of transistors included in the display portion 662 may have the same structure or different structures.

A material through which impurities such as water and hydrogen do not easily diffuse is preferably used for at least one of the insulating films 682 and 683 which cover the transistors. That is, the insulating film 682 or the insulating film 683 can function as a barrier film. Such a structure can effectively suppress diffusion of the impurities into the transistors from the outside, and a highly reliable display panel can be provided.

The insulating film 621 is provided on the substrate 661 side to cover the coloring layer 631 and the light-blocking film 632. The insulating film 621 may have a function as a planarization layer. The insulating film 621 enables the conductive film 613 to have an almost flat surface, resulting in a uniform alignment state of the liquid crystal layer 612.

An example of the method for manufacturing the display panel 600 is described. For example, the conductive film 635, the conductive film 663, and the insulating film 620 are formed in order over a support substrate provided with a separation layer, and the transistor 605, the transistor 606, the light-emitting element 660, and the like are formed. Then, the substrate 651 and the support substrate are bonded with the adhesive layer 642. After that, separation is performed at the interface between the separation layer and each of the insulating film 620 and the conductive film 635, whereby the support substrate and the separation layer are removed. Separately, the coloring layer 631, the light-blocking film 632, the conductive film 613, and the like are formed over the substrate 661 in advance. Then, the liquid crystal is dropped onto the substrate 651 or 661 and the substrates 651 and 661 are bonded with the adhesive layer 641, whereby the display panel 600 can be manufactured.

A material for the separation layer can be selected as appropriate such that separation at the interface with the insulating film 620 and the conductive film 635 occurs. In particular, it is preferable that a stacked layer of a layer including a high-melting-point metal material, such as tungsten, and a layer including an oxide of the metal material be used as the separation layer, and a stacked layer of a plurality of layers, such as a silicon nitride layer, a silicon oxynitride layer, and a silicon nitride oxide layer be used as the insulating film 620 over the separation layer. The use of the high-melting-point metal material for the separation layer can increase the formation temperature of a layer formed in a later step, which reduces the impurity concentration and achieves a highly reliable display panel.

As the conductive film 635, a metal oxide or a metal nitride is preferably used.

### <4-3. Components>

The above components are described below. Note that the description of structures having functions similar to those in the above embodiments is omitted.

### [Adhesive Layer]

As the adhesive layer, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferred. Alternatively, a two-component-mixture-type resin may be used. Alternatively, an adhesive sheet or the like may be used.

Furthermore, the resin may contain a drying agent. For example, a substance that adsorbs moisture by chemical adsorption, such as an oxide of an alkaline earth metal (e.g., calcium oxide or barium oxide), can be used. Alternatively, a substance that adsorbs moisture by physical adsorption, such as zeolite or silica gel, may be used. The drying agent is preferably included because it can prevent impurities such as moisture from entering the element, thereby improving the reliability of the display panel.

In addition, it is preferable to mix a filler with a high refractive index or a light-scattering member into the resin, in which case light extraction efficiency can be enhanced. For example, titanium oxide, barium oxide, zeolite, or zirconium can be used.

### [Connection Layer]

As the connection layer, an anisotropic conductive film (ACF), an anisotropic conductive paste (ACP), or the like can be used.

### [Coloring Layer]

Examples of a material that can be used for the coloring layer include a metal material, a resin material, and a resin material containing a pigment or dye.

### [Light-Blocking Layer]

Examples of a material that can be used for the light-blocking layer include carbon black, titanium black, a metal, a metal oxide, and a composite oxide containing a solid solution of a plurality of metal oxides. The light-blocking layer may be a film containing a resin material or a thin film of an inorganic material such as a metal. Stacked films containing the material of the coloring layer can also be used for the light-blocking layer. For example, a stacked-layer structure of a film containing a material of a coloring layer which transmits light of a certain color and a film containing a material of a coloring layer which transmits light of another color can be employed. It is preferable that the coloring layer and the light-blocking layer be formed using the same material because the same manufacturing apparatus can be used and the process can be simplified.

The above is the description of the components.

### <4-4. Manufacturing Method Example>

A manufacturing method example of a display panel using a flexible substrate is described.

Here, layers including a display element, a circuit, a wiring, an electrode, optical members such as a coloring layer and a light-blocking layer, an insulating layer, and the like, are collectively referred to as an element layer. The element layer includes, for example, a display element, and may additionally include a wiring electrically connected to the display element or an element such as a transistor used in a pixel or a circuit.

In addition, here, a flexible member which supports the element layer at a stage at which the display element is completed (the manufacturing process is finished) is referred to as a substrate. For example, a substrate includes an extremely thin film with a thickness greater than or equal to 10 nm and less than or equal to 300 μm and the like.

As a method for forming an element layer over a flexible substrate provided with an insulating surface, typically, there are two methods described below. One of them is to directly form an element layer over the substrate. The other method is to form an element layer over a support substrate that is different from the substrate and then to separate the element layer from the support substrate to be transferred to the substrate. Although not described in detail here, in addition to the above two methods, there is a method in which an element layer is formed over a substrate which does not have flexibility and the substrate is thinned by polishing or the like to have flexibility.

In the case where a material of the substrate can withstand heating temperature in a process for forming the element layer, it is preferable that the element layer be formed directly over the substrate, in which case a manufacturing process can be simplified. At this time, the element layer is preferably formed in a state where the substrate is fixed to the support substrate, in which case transfer thereof in an apparatus and between apparatuses can be easy.

In the case of employing the method in which the element layer is formed over the support substrate and then transferred to the substrate, first, a separation layer and an insulating layer are stacked over the support substrate, and then the element layer is formed over the insulating layer. Next, the element layer is separated from the support substrate and then transferred to the substrate. At this time, a material is selected such that separation occurs at an interface between the support substrate and the separation layer, at an interface between the separation layer and the insulating layer, or in the separation layer. With the method, it is preferable that a material having high heat resistance be used for the support substrate or the separation layer, in which case the upper limit of the temperature applied when the element layer is formed can be increased, and an element layer including a more reliable element can be formed.

For example, it is preferable that a stacked layer of a layer containing a high-melting-point metal material, such as tungsten, and a layer containing an oxide of the metal material be used as the separation layer, and a stacked layer of a plurality of layers, such as a silicon oxide layer, a silicon nitride layer, a silicon oxynitride layer, and a silicon nitride oxide layer be used as the insulating layer over the separation layer.

The element layer and the support substrate can be separated by applying mechanical power, by etching the separation layer, or by injecting a liquid into the separation interface, for example. Alternatively, separation may be performed by heating or cooling two layers of the separation interface by utilizing a difference in thermal expansion coefficient.

The separation layer is not necessarily provided in the case where separation can occur at the interface between the support substrate and the insulating layer.

For example, glass and an organic resin such as polyimide can be used as the support substrate and the insulating layer, respectively. In that case, a separation trigger may be formed by, for example, locally heating part of the organic resin with laser light or the like, or by physically cutting part of or making a hole through the organic resin with a sharp tool, and separation may be performed at an interface between the glass and the organic resin. As the above-described organic resin, a photosensitive material is preferably used because an opening or the like can be easily formed. The above-described laser light preferably has a wavelength region, for example, from visible light to ultraviolet light. For example, light having a wavelength greater than or equal to 200 nm and less than or equal to 400 nm, preferably greater than or equal to 250 nm and less than or equal to 350 nm can be used. In particular, an excimer laser having a wavelength of 308 nm is preferably used because the productivity is increased. Alternatively, a solid-state UV laser (also referred to as a semiconductor UV laser), such as a UV laser having a wavelength of 355 nm which is the third harmonic of an Nd:YAG laser, may be used.

Alternatively, a heat generation layer may be provided between the support substrate and the insulating layer formed of an organic resin, and separation may be performed at an interface between the heat generation layer and the insulating layer by heating the heat generation layer. The heat generation layer can be formed using a variety of materials such as a material that generates heat when current flows therethrough, a material that generates heat when it absorbs light, and a material that generates heat when a magnetic field is applied thereto. For example, a material for the heat generation layer can be selected from a semiconductor, a metal, and an insulator.

In the above-described methods, the insulating layer formed of an organic resin can be used as a substrate after the separation.

The above is the description of a manufacturing method of a flexible display panel.

At least part of this embodiment can be implemented in combination with any of the other embodiments described in this specification as appropriate.

### Embodiment 5

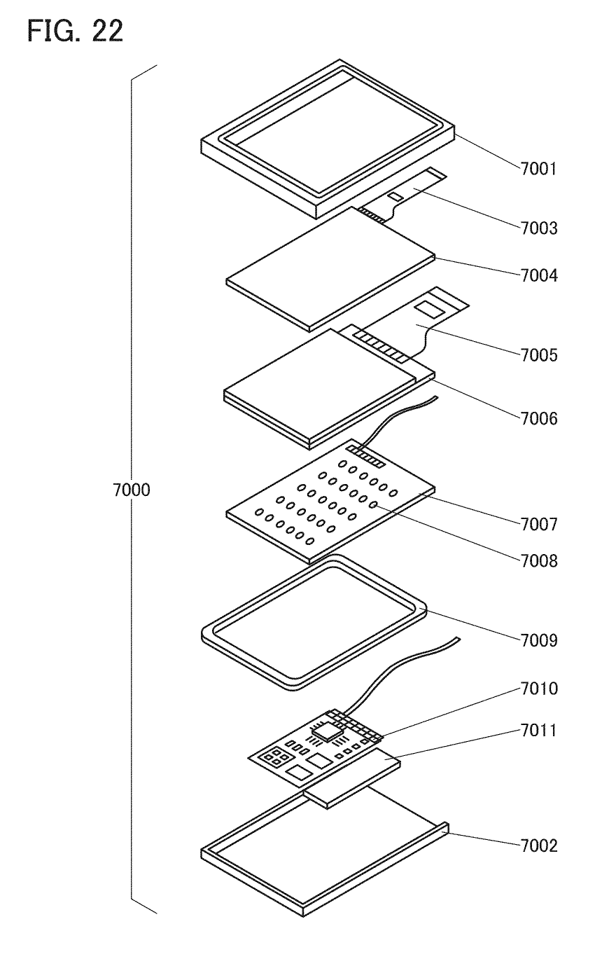

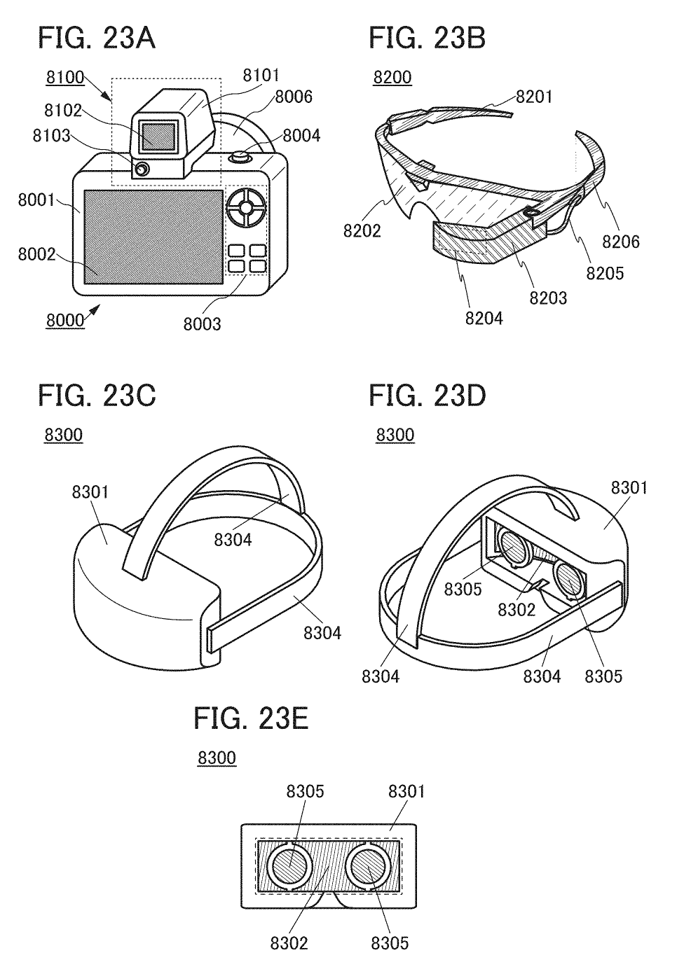

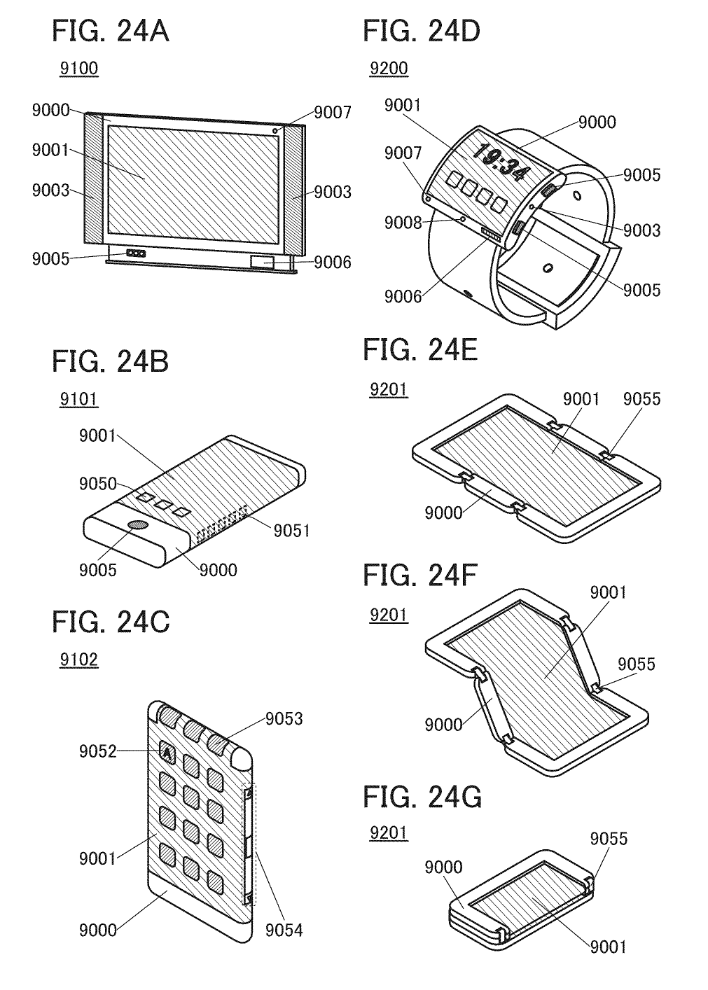

In this embodiment, a display module and electronic devices, each of which includes a semiconductor device of one embodiment of the present invention, are described with reference to FIG. 22, FIGS. 23A to 23E, and FIGS. 24A to 24G.

### <5-1. Display Module>

In a display module 7000 illustrated in FIG. 22, a touch panel 7004 connected to an FPC 7003, a display panel 7006 connected to an FPC 7005, a backlight 7007, a frame 7009, a printed-circuit board 7010, and a battery 7011 are provided between an upper cover 7001 and a lower cover 7002.

The semiconductor device of one embodiment of the present invention can be used for the display panel 7006, for example.

The shapes and sizes of the upper cover 7001 and the lower cover 7002 can be changed as appropriate in accordance with the sizes of the touch panel 7004 and the display panel 7006.

The touch panel 7004 can be a resistive touch panel or a capacitive touch panel and overlap with the display panel 7006. Alternatively, a counter substrate (sealing substrate) of the display panel 7006 can have a touch panel function. Alternatively, a photosensor may be provided in each pixel of the display panel 7006 to form an optical touch panel.

The backlight 7007 includes a light source 7008. One embodiment of the present invention is not limited to the structure in FIG. 22, in which the light source 7008 is provided over the backlight 7007. For example, a structure in which the light source 7008 is provided at an end portion of the backlight 7007 and a light diffusion plate is further provided may be employed. Note that the backlight 7007 is not necessarily provided in the case where a self-luminous light-emitting element such as an organic EL element is used or in the case where a reflective panel or the like is employed.

The frame 7009 protects the display panel 7006 and functions as an electromagnetic shield for blocking electromagnetic waves generated by the operation of the printed-circuit board 7010. The frame 7009 may also function as a radiator plate.

The printed-circuit board 7010 includes a power supply circuit and a signal processing circuit for outputting a video signal and a clock signal. As a power source for supplying power to the power supply circuit, an external commercial power source or the separate battery 7011 may be used. The battery 7011 can be omitted in the case where a commercial power source is used.

The display module 7000 may be additionally provided with a member such as a polarizing plate, a retardation plate, or a prism sheet.

### <5-2. Electronic Device 1>

Next, FIGS. 23A to 23E illustrate examples of electronic devices.

FIG. 23A is an external view of a camera 8000 to which a finder 8100 is attached.

The camera 8000 includes a housing 8001, a display portion 8002, operation buttons 8003, a shutter button 8004, and the like. Furthermore, a detachable lens 8006 is attached to the camera 8000.

Although the lens 8006 of the camera 8000 here is detachable from the housing 8001 for replacement, the lens 8006 may be included in the housing 8001.

Images can be taken with the camera 8000 at the press of the shutter button 8004. In addition, images can be taken at the touch of the display portion 8002 which serves as a touch panel.

The housing 8001 of the camera 8000 includes a mount including an electrode, so that the finder 8100, a stroboscope, or the like can be connected to the housing 8001.

The finder 8100 includes a housing 8101, a display portion 8102, a button 8103, and the like.

The housing 8101 includes a mount for engagement with the mount of the camera 8000 so that the finder 8100 can be connected to the camera 8000. The mount includes an electrode, and an image or the like received from the camera 8000 through the electrode can be displayed on the display portion 8102.

The button 8103 serves as a power button. The display portion 8102 can be turned on and off with the button 8103.

A display device of one embodiment of the present invention can be used in the display portion 8002 of the camera 8000 and the display portion 8102 of the finder 8100.

Although the camera 8000 and the finder 8100 are separate and detachable electronic devices in FIG. 23A, the housing 8001 of the camera 8000 may include a finder having a display device.

FIG. 23B is an external view of a head-mounted display 8200.

The head-mounted display 8200 includes a mounting portion 8201, a lens 8202, a main body 8203, a display portion 8204, a cable 8205, and the like. The mounting portion 8201 includes a battery 8206.

Power is supplied from the battery 8206 to the main body 8203 through the cable 8205. The main body 8203 includes a wireless receiver or the like to receive video data, such as image data, and display it on the display portion 8204. The movement of the eyeball and the eyelid of a user is captured by a camera in the main body 8203 and then coordinates of the points the user looks at are calculated using the captured data to utilize the eye of the user as an input means.

The mounting portion 8201 may include a plurality of electrodes so as to be in contact with the user. The main body 8203 may be configured to sense current flowing through the electrodes with the movement of the user's eyeball to recognize the direction of his or her eyes. The main body 8203 may be configured to sense current flowing through the electrodes to monitor the user's pulse. The mounting portion 8201 may include sensors, such as a temperature sensor, a pressure sensor, or an acceleration sensor so that the user's biological information can be displayed on the display portion 8204. The main body 8203 may be configured to sense the movement of the user's head or the like to move an image displayed on the display portion 8204 in synchronization with the movement of the user's head or the like.

The display device of one embodiment of the present invention can be used in the display portion 8204.

FIGS. 23C to 23E are external views of a head-mounted display 8300. The head-mounted display 8300 includes a housing 8301, a display portion 8302, a fixing band 8304, and a pair of lenses 8305.

A user can see display on the display portion 8302 through the lenses 8305. It is favorable that the display portion 8302 be curved. When the display portion 8302 is curved, a user can feel high realistic sensation of images. Although the structure described in this embodiment as an example has one display portion 8302, the number of display portions 8302 provided is not limited to one. For example, two display portions 8302 may be provided, in which case one display portion is provided for one corresponding user's eye, so that three-dimensional display using parallax or the like is possible.

The display device of one embodiment of the present invention can be used in the display portion 8302. The display device including the semiconductor device of one embodiment of the present invention has an extremely high resolution; thus, even when an image is magnified using the lenses 8305 as illustrated in FIG. 23E, the user does not perceive pixels, and thus a more realistic image can be displayed.

### <5-3. Electronic Device 2>

Next, FIGS. 24A to 24G illustrate examples of electronic devices that are different from those illustrated in FIGS. 23A to 23E.

Electronic devices illustrated in FIGS. 24A to 24G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 9008, and the like.

The electronic devices illustrated in FIGS. 24A to 24G can have a variety of functions, for example, a function of displaying a variety of information (e.g., a still image, a moving image, and a text image) on the display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a memory medium and displaying it on the display portion. Note that functions of the electronic devices illustrated in FIGS. 24A to 24G are not limited thereto, and the electronic devices can have a variety of functions. Although not illustrated in FIGS. 24A to 24G, the electronic devices may each include a plurality of display portions. The electronic devices may each include a camera and the like and have a function of taking a still image, a function of taking a moving image, a function of storing the taken image in a memory medium (an external memory medium or a memory medium incorporated in the camera), a function of displaying the taken image on the display portion, or the like.

The electronic devices illustrated in FIGS. 24A to 24G are described in detail below.

FIG. 24A is a perspective view of a television device 9100. The television device 9100 can include the display portion 9001 having a large screen size of, for example, 50 inches or more, or 100 inches or more.

FIG. 24B is a perspective view of a portable information terminal 9101. The portable information terminal 9101 functions as, for example, one or more of a telephone set, a notebook, and an information browsing system. Specifically, the portable information terminal 9101 can be used as a smartphone. Note that the portable information terminal 9101 may include the speaker, the connection terminal, the sensor, or the like. The portable information terminal 9101 can display characters and image information on its plurality of surfaces. For example, three operation buttons 9050 (also referred to as operation icons, or simply as icons) can be displayed on one surface of the display portion 9001. Furthermore, information 9051 indicated by dashed rectangles can be displayed on another surface of the display portion 9001. Examples of the information 9051 include display indicating reception of an e-mail, a social networking service (SNS) message, a telephone call, and the like, the title and sender of an e-mail or an SNS message, date, time, remaining battery, and reception strength of an antenna. Alternatively, the operation buttons 9050 or the like may be displayed in place of the information 9051.

FIG. 24C is a perspective view of a portable information terminal 9102. The portable information terminal 9102 has a function of displaying information on three or more surfaces of the display portion 9001. Here, information 9052, information 9053, and information 9054 are displayed on different surfaces. For example, a user of the portable information terminal 9102 can see the display (here, the information 9053) with the portable information terminal 9102 put in a breast pocket of his/her clothes. Specifically, a caller's phone number, name, or the like of an incoming call is displayed in a position that can be seen from above the portable information terminal 9102. Thus, the user can see the display without taking out the portable information terminal 9102 from the pocket and decide whether to answer the call.

FIG. 24D is a perspective view of a watch-type portable information terminal 9200. The portable information terminal 9200 is capable of executing a variety of applications such as mobile phone calls, e-mailing, reading and editing texts, music reproduction, Internet communication, and computer games. The display surface of the display portion 9001 is curved, and images can be displayed on the curved display surface. The portable information terminal 9200 can employ near field communication conformable to a communication standard. For example, hands-free calling can be achieved by mutual communication between the portable information terminal 9200 and a headset capable of wireless communication. The portable information terminal 9200 includes the connection terminal 9006, and data can be directly transmitted to and received from another information terminal via a connector. Power charging through the connection terminal 9006 is also possible. Note that the charging operation may be performed by wireless power feeding without using the connection terminal 9006.

FIGS. 24E to 24G are perspective views of a foldable portable information terminal 9201. FIG. 24E is a perspective view of the portable information terminal 9201 that is opened. FIG. 24F is a perspective view of the portable information terminal 9201 that is being opened or being folded. FIG. 24G is a perspective view of the portable information terminal 9201 that is folded. The portable information terminal 9201 is highly portable when folded. When the portable information terminal 9201 is opened, a seamless large display region is highly browsable. The display portion 9001 of the portable information terminal 9201 is supported by three housings 9000 joined by hinges 9055. By folding the portable information terminal 9201 at a connection portion between two housings 9000 with the hinges 9055, the portable information terminal 9201 can be reversibly changed in shape from the opened state to the folded state. For example, the portable information terminal 9201 can be bent with a radius of curvature of greater than or equal to 1 mm and less than or equal to 150 mm.

The electronic devices described in this embodiment each include the display portion for displaying some sort of data. Note that the semiconductor device of one embodiment of the present invention can also be used for an electronic device that does not include a display portion.

At least part of this embodiment can be implemented in combination with any of the other embodiments described in this specification as appropriate.

This application is based on Japanese Patent Application Serial No. 2016-145096 filed with Japan Patent Office on Jul. 25, 2016, the entire contents of which are hereby incorporated by reference.

What is claimed is:

1. A method for manufacturing a semiconductor device, comprising the steps of:
forming a metal oxide over a first insulating film;
forming a source electrode and a drain electrode over the metal oxide; and
forming a second insulating film over and in contact with the metal oxide, the source electrode, and the drain electrode,
wherein the second insulating film is formed in a vacuum chamber of a chemical vapor deposition apparatus by the steps of:
supplying a source gas to the vacuum chamber and attaching the source gas to the metal oxide;
evacuating the source gas; and
supplying at least one of a nitrogen gas and an oxygen gas to the vacuum chamber and generating plasma on the metal oxide.

2. The method for manufacturing a semiconductor device according to claim 1, wherein the metal oxide is a semiconductor film of a transistor.

3. The method for manufacturing a semiconductor device according to claim 1, wherein the metal oxide is an oxide semiconductor comprising indium and zinc.

4. The method for manufacturing a semiconductor device according to claim 1, further comprising the steps of:
forming a gate electrode over a substrate; and
forming the first insulating film over the gate electrode.

5. The method for manufacturing a semiconductor device according to claim 1, wherein the source gas comprises silane.

6. A method for manufacturing a semiconductor device, comprising the steps of:
forming a metal oxide over a first insulating film;
forming a source electrode and a drain electrode over the metal oxide; and
forming a second insulating film over and in contact with the metal oxide, the source electrode, and the drain electrode,
wherein the second insulating film is formed in a vacuum chamber of a chemical vapor deposition apparatus by the steps of:
supplying a source gas to the vacuum chamber and attaching the source gas to the metal oxide;
evacuating the source gas;
forming a first layer of the second insulating film by supplying an oxygen gas to the vacuum chamber and generating plasma on the metal oxide; and
forming a second layer of the second insulating film by supplying a nitrogen gas to the vacuum chamber and generating plasma on the first layer,
wherein the first layer comprises silicon and oxygen, and
wherein the second layer comprises silicon and nitrogen.

7. The method for manufacturing a semiconductor device according to claim 6, further comprising the steps of:
supplying the source gas to the vacuum chamber and attaching the source gas to the first layer; and
evacuating the source gas before the step of forming the second layer.

8. The method for manufacturing a semiconductor device according to claim 6, further comprising the step of adding oxygen to the first layer.

9. The method for manufacturing a semiconductor device according to claim 6, wherein the metal oxide is a semiconductor film of a transistor.

10. The method for manufacturing a semiconductor device according to claim 6, wherein the metal oxide is an oxide semiconductor comprising indium and zinc.

11. The method for manufacturing a semiconductor device according to claim 6, further comprising the steps of:
forming a gate electrode over a substrate; and
forming the first insulating film over the gate electrode.

12. The method for manufacturing a semiconductor device according to claim 6, wherein the source gas comprises silane.

13. A method for manufacturing a semiconductor device, comprising the steps of:
forming a first metal oxide over a first insulating film;
forming a second metal oxide over the first metal oxide;
forming a source electrode and a drain electrode over the second metal oxide; and
forming a second insulating film over and in contact with the second metal oxide, the source electrode, and the drain electrode,
wherein the second insulating film is formed by a plasma assisted atomic layer deposition method.

14. The method for manufacturing a semiconductor device according to claim 13, wherein a thickness of the second insulating film is smaller than a thickness of the second metal oxide.

15. The method for manufacturing a semiconductor device according to claim 13, wherein crystallinity of the first metal oxide is lower than crystallinity of the second metal oxide.

16. The method for manufacturing a semiconductor device according to claim 13, wherein each of the first metal oxide and the second metal oxide is a semiconductor film of a transistor.

17. The method for manufacturing a semiconductor device according to claim 13, wherein each of the first metal oxide and the second metal oxide is an oxide semiconductor comprising indium and zinc.

18. The method for manufacturing a semiconductor device according to claim 13, further comprising the steps of:
forming a gate electrode over a substrate; and
forming the first insulating film over the gate electrode.
